(19) United States
(12) Patent Application Publication
(10) Pub. No.: US 2026/0203887 A1
(43) Pub. Date: Jul. 16, 2026

(54) PROCESSING TOOL WITH HYPERSPECTRAL CAMERA FOR METROLOGY-BASED ANALYSIS

(71) Applicant: Lam Research Corporation, Fremont, CA (US)

(72) Inventors: Kapil SAWLANI, Ann Arbor, MI (US); Patging John Elsworth MARTIN, Portland, OR (US); Paul FRANZEN, West Linn, OR (US); Michael CHRISTENSEN, Tualatin, OR (US); David PORTER, Sherwood, OR (US)

(21) Appl. No.: 19/130,939

(22) PCT Filed: Dec. 7, 2023
(86) PCT No.: PCT/US2023/082977

§ 371 Date: May 16, 2025

Related U.S. Application Data
(60) Provisional application No. 63/386,645, filed on Dec. 8, 2022.

(51) Int. Cl. G06T 7/00; H04N 23/10; H04N 23/56; H10P 72/00

(52) U.S. Cl. CPC G06T 7/0004; H04N 23/10; H10P 72/0616; G06T 2207/10016; G06T 2207/30148; G06T 2207/30242; H04N 23/56

(57) ABSTRACT

Examples are disclosed that relate to a processing tool including a hyperspectral camera configured to acquire hyperspectral imagery of a processing chamber of the processing tool and/or a substrate in the processing tool. Metrology data derived from the hyperspectral imagery is used to control operation of the processing tool.

### BACKGROUND

Semiconductor device manufacturing involves many steps of material deposition, patterning, and removal to form devices on substrates. Metrology-based analyses can be performed on substrates throughout production for quality control checks. Example metrological analyses that can be performed on substrates include film thickness, non-uniformity, refractive index (RI), stress, particles, and Fourier Transform Infrared (FTIR) spectroscopy.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to a processing tool including a hyperspectral camera configured to acquire hyperspectral imagery of a processing chamber of the processing tool and/or a substrate in the processing tool. Metrology data derived from the hyperspectral imagery is used to control operation of the processing tool.

In one example, a processing tool comprises a processing chamber comprising an optical interface, and a hyperspectral camera arranged to capture hyperspectral images of an interior of the processing chamber through the optical interface of the processing chamber.

In some such examples, the processing chamber alternatively or additionally comprises a pedestal, and the hyperspectral camera is arranged to capture hyperspectral images of a substrate positioned on the pedestal through the optical interface.

In some such examples, the processing chamber alternatively or additionally comprises a showerhead situated opposite the pedestal, and the optical interface is disposed on the showerhead.

In some such examples, the optical interface alternatively or additionally is disposed on the pedestal.

In some such examples, the optical interface alternatively or additionally is disposed on a sidewall of the processing chamber.

In some such examples, the processing tool alternatively or additionally further comprises one or more optical elements arranged between the optical interface and the hyperspectral camera, and the one or more optical elements are configured to direct electromagnetic radiation passing through the optical interface to the hyperspectral camera.

In some such examples, the processing chamber alternatively or additionally is a plasma reactor chamber.

In some such examples, the processing tool alternatively or additionally further comprises a computing system configured to execute a trained machine-learning model. The trained machine-learning model is configured to receive one or more hyperspectral images from the hyperspectral camera and output metrology data for the processing chamber based at least on the one or more hyperspectral images.

In some such examples, the computing system alternatively or additionally is configured to adjust a control parameter of a cleaning process to clean the processing chamber based at least on the metrology data for the processing chamber.

In some such examples, the trained machine-learning model alternatively or additionally is configured to receive a series of hyperspectral images of a substrate in the processing chamber during a substrate processing cycle and output time-based metrology data for the substrate based at least on the series of hyperspectral images of the substrate. The computing system is configured to, during the substrate processing cycle, adjust one or more control parameters of a process of the substrate processing cycle based at least on the time-based metrology data for the substrate.

In some such examples, the trained machine-learning model alternatively or additionally is configured to receive one or more hyperspectral images of a first substrate in the processing chamber during or after a first substrate processing cycle and output metrology data for the first substrate based at least on the one or more hyperspectral images of the first substrate. The computing system is configured to, for a second substrate processing cycle for a second substrate, adjust one or more control parameters of a process of the second substrate processing cycle based at least on the metrology data for the first substrate.

In another example, a computer-implemented method for controlling a processing tool comprises receiving one or more hyperspectral images of a processing chamber of the processing tool from a hyperspectral camera, sending the one or more hyperspectral images to a trained machine-learning model configured to output metrology data for the processing chamber based at least on the one or more hyperspectral images, and adjusting one or more control parameters of a process performed by the processing tool based at least on the metrology data for the processing chamber.

In some such examples, the process alternatively or additionally comprises a cleaning process to clean the processing chamber, and the one or more control parameters comprise a control parameter of the cleaning process.

In some such examples, the one or more hyperspectral images alternatively or additionally comprise a series of hyperspectral images of a substrate in the processing chamber. The series of hyperspectral images of the substrate are received from the hyperspectral camera during a substrate processing cycle for the substrate. The trained machine-learning model is configured to output time-based metrology data for the substrate, and the one or more control parameters are adjusted during the substrate processing cycle for the substrate based at least on the time-based metrology data for the substrate.

In some such examples, the one or more hyperspectral images alternatively or additionally comprise one or more hyperspectral images of a first substrate in the processing chamber during or after a first substrate processing cycle, and the one or more control parameters are adjusted for a second substrate processing cycle for a second substrate based at least on the metrology data for the first substrate.

In some such examples, the processing chamber alternatively or additionally is a plasma reactor chamber, and the one or more hyperspectral images of the plasma reactor chamber are captured by the hyperspectral camera while plasma is present in the plasma reactor chamber, and the plasma in the plasma reactor chamber is an illumination source for the hyperspectral camera.

In another example, a processing tool comprises a hyperspectral camera arranged to capture hyperspectral images of a substrate in the processing tool, and a computing system configured to execute a trained machine-learning model, the trained machine-learning model configured to receive one or more hyperspectral images from the hyperspectral camera and output metrology data for the substrate based at least on the one or more hyperspectral images.

In some such examples, the metrology data includes a thickness of one or more layers of the substrate.

In some such examples, alternatively or additionally the metrology data includes a state of a gap in the substrate.

In some such examples, alternatively or additionally the hyperspectral camera has a dynamically adjustable position.

In some such examples, alternatively or additionally the hyperspectral camera has a dynamically adjustable angle.

In some such examples, alternatively or additionally the metrology data includes a determined amount of stress and/or bow in the substrate.

In some such examples, alternatively or additionally the metrology data includes a determined amount of haze in the substrate.

### BRIEF DESCRIPTION OF THE DRAWINGS

FIG. 1 shows a block diagram of an example processing tool.

FIGS. 2-7 schematically show different example arrangements of a hyperspectral camera in a processing chamber.

FIG. 8 schematically shows an example hyperspectral image captured by a hyperspectral camera.

FIG. 9 shows a flow diagram depicting an example method of training and executing a machine-learning model to perform metrology-based analysis on a processing chamber and/or a substrate in a processing chamber.

FIG. 10 shows a flow diagram depicting an example method of performing hyperspectral image-based metrology-based analysis to control a cleaning process of a processing chamber.

FIG. 11 shows a flow diagram depicting an example method of performing hyperspectral image-based metrology-based analysis for in-situ control of a processing tool during a substrate processing cycle.

FIG. 12 shows a flow diagram depicting an example method of performing hyperspectral image-based metrology-based analysis for ex-situ in-line control of a processing tool between substrate processing cycles.

FIG. 13 shows a block diagram of an example computing system.

FIG. 14 schematically shows different example states of a substrate during a process in which a gap of the substrate is being filled.

FIG. 15 schematically shows different example states of a substrate as a result of a fill process in which a gap of the substrate is filled.

FIG. 16 schematically shows an example scenario where a hyperspectral camera is configured to be dynamically adjustable in order to adjust a distance of the hyperspectral camera relative to a substrate being imaged.

FIG. 17 schematically shows an example scenario where a hyperspectral camera is configured to be dynamically adjustable in order to adjust an angle of the hyperspectral camera relative to a substrate being imaged.

FIG. 18 shows an example graph of a plurality of plots of spectral reflectance of a material on a substrate that vary as a function of wavelength and an angle of incidence of light on the material.

FIG. 19 shows an example graph of two plots of spectral reflectance of two different substrates that vary as a function of wavelength and a number of layers of the two different substrates.

FIGS. 20-22 schematically show example configurations in which a hyperspectral camera can be used to measure stress and/or bow of a substrate.

FIGS. 23-24 show example graphs of spectral reflectance measured in different wavelengths at different points on a substrate to measure stress and/or bow at the different points on the substrate.

FIG. 25 shows an example configuration in which a hyperspectral camera is configured to measure haze on a substrate.

FIGS. 26-27 schematically show example arrangements of spatially separated light emitters in a light source of a hyperspectral camera used to measure haze of a substrate.

FIG. 28 shows an example graph of the electromagnetic spectrum including different ranges of wavelength that can be used for different operations including measuring haze of a substrate.

FIG. 29 shows an example graph including a haze measurement represented in terms of a number of pixels with reflected light and their corresponding intensity.

FIG. 30 schematically shows an example processing tool including a plurality of hyperspectral cameras.

FIG. 31 schematically shows an example processing module including a plurality of hyperspectral cameras.

FIG. 32 shows a flow diagram depicting an example method of dynamically controlling the position of a hyperspectral camera in a processing tool to vary a distance between the hyperspectral camera and a substrate for hyperspectral imaging and analysis.

FIG. 33 shows a flow diagram depicting an example method of dynamically controlling the position of a hyperspectral camera to capture hyperspectral images of different substrates from different angles.

FIG. 34 shows a flow diagram depicting an example method of performing metrology-based analysis using hyperspectral images for control of a processing tool.

### DETAILED DESCRIPTION

The term “atomic layer deposition” (ALD) generally represents a process in which a film is formed on a substrate in one or more individual layers by sequentially adsorbing a precursor conformally to the substrate and reacting the adsorbed precursor to form a film layer. Examples of ALD processes comprise plasma-enhanced ALD (PEALD) and thermal ALD (TALD). PEALD and TALD respectively utilize a plasma of a reactive gas and heat to facilitate a chemical conversion of a precursor adsorbed to a substrate to a film on the substrate.

The term “chemical vapor deposition” (CVD) generally represents a process in which a solid phase film is formed on a substrate by directing a flow of one or more precursor gases over the substrate surface under conditions configured to cause the chemical conversion of the precursor gases to the solid phase film. The term “plasma-enhanced chemical-vapor deposition” (PECVD) generally represents a CVD process in which a plasma is used to facilitate the chemical conversion of one or more precursor gases to a solid phase film on a substrate.

The term “cleaning process” generally represents a process of cleaning deposited materials from interior surfaces of a processing chamber. Deposited materials can include materials being deposited on substrates in a deposition process, byproducts of a deposition process, residues from an etching process, and/or a coating of one or more materials applied to a processing chamber before performing a deposition or etching process.

The term “control parameter” generally represents a controllable variable in a process carried out in a process chamber. Example control parameters include the temperature of a heater, a pressure within the chamber, a flow rate of each of one or more processing gases, and a frequency and power level of a radiofrequency power used to form a plasma in the processing chamber.

The term “disposed on” generally represents a structural relationship in which a part is supported by another part. The term “disposed on” by itself does not represent a specific relative positioning of the part to the other part. For example, an optical interface disposed on a part of a processing chamber or a component of the processing chamber can be flush with a surface of the part or component, can be inset from a surface of the part or component, or can extend beyond a surface of the part or component.

The term “etch” and variants thereof generally represent removal of material from a structure. Substrates can be etched by a plasma in a plasma processing tool.

The term “hyperspectral camera” generally represents an optical device configured to acquire a hyperspectral image.

The term “hyperspectral image” generally represents a data structure having a plurality of sub-images. Each different sub-image corresponds to a different wavelength or wavelength band of electromagnetic radiation. Each sub-image is a two-dimensional array of pixels. Each pixel of each sub-image stores an intensity value. The intensity value is an intensity of electromagnetic radiation at the corresponding wavelength or wavelength band for that sub-image that was received from a corresponding spatial location in a processing chamber. In some examples, a hyperspectral image may include one hundred or more sub-images corresponding to different wavelengths or wavelength bands. In other examples, the hyperspectral image may take the form of a multispectral image including a plurality of sub-images each corresponding selected wavelength band associated with a different descriptive channel names. Examples of wavelength bands and descriptive channel names include BLUE in band 2 (0.45-0.51 micrometer (um)), GREEN in band 3 (0.53-0.59 um), RED in band 4 (0.64-0.67 um), NEAR INFRARED (NIR) in band 5 (0.85-0.88 um), SHORT-WAVE INFRARED (SWIR 1) in band 6 (1.57-1.65 um), SHORT-WAVE INFRARED (SWIR 2) in band 7 (2.11-2.29 um), PANCHROMATIC in band 8 (0.50-0.68 um), CIRRUS in band 9 (1.36-1.38 um), THERMAL INFRARED (TIRS 1) in band 10 (10.60-11.19 um), THERMAL INFRARED (TIRS 2) in band 11 (11.50-12.51 um). A multispectral camera can image restricted wavelength bands of interest in some examples.

The term “illumination source” generally represents a source that provides illumination light for a hyperspectral camera to capture images.

The term “inhibitor” generally represents a compound that can be introduced into a processing chamber, which can be deposited nonconformally on a substrate surface, and that inhibits ALD growth of an oxide film.

The term “metrology data” generally represents data acquired by making measurements of one or more observable properties. For example, a hyperspectral camera can be used to acquire metrology data comprising electromagnetic energy intensities originating from different spatial locations in a processing chamber. Example observable properties include film thickness, non-uniformity, refractive index (RI), stress, particle detection, and Fourier Transform Infrared (FTIR) spectroscopy. One or more of such observable properties can be used for calibration and verification of a hyperspectral metrology model.

The term “optical interface” generally represents an optically transparent structure positioned between an interior of a processing chamber and an exterior of the processing chamber for performing hyperspectral imaging of the processing chamber through the optical interface. The term “interior of the processing chamber” indicates a volume of space in which a substrate is located during processing. An optical interface can be located on a wall of a processing chamber or on a structure within the processing chamber, such as a pedestal or a showerhead. An optical interface passes electromagnetic radiation for hyperspectral imaging to a hyperspectral camera while preventing the passage of gases.

The term “optical element” generally represents a structure that is configured to direct and/or modify electromagnetic radiation along an optical path. Example optical elements include optical fibers and other waveguides, diffractive and refractive lenses and mirrors, and polarizers and other filters.

The term “optically transparent” with reference to a material generally represents that the material is suitably transparent to electromagnetic energy bands being imaged by a hyperspectral camera to acquire useful hyperspectral data.

The term “pedestal” generally represents a structure that supports a substrate in a processing chamber.

The term “plasma” generally represents an ionized gas comprising gas-phase cations and free electrons.

The term “plasma reactor chamber” generally represents a processing chamber in which a plasma can be generated for performing chemical processes on substrates.

The term “processing chamber” generally represents an enclosure in which chemical and/or physical processes are performed on substrates. The pressure, temperature, gas flow rate, and atmospheric composition within a processing chamber can be controllable to perform chemical and/or physical processes. Controllable aspects of atmospheric composition include one or more of gas mixture or plasma conditions.

The term “processing tool” generally represents a machine comprising a processing chamber and other hardware configured to perform a substrate processing cycle.

The term “showerhead” generally represents a structure for distributing gases across a substrate surface in a processing chamber.

The term “substrate” generally represents any object that can be positioned on a pedestal in a processing tool for processing.

The term “substrate processing cycle” generally represents a set of one or more processes used to cause a physical and/or chemical change on a substrate. For example, a substrate processing cycle can comprise a deposition cycle in which a thin film is formed on the substrate. A deposition cycle can be performed by a chemical vapor deposition (CVD) process or an atomic layer deposition (ALD) process, as examples. A substrate processing cycle also can comprise an etching cycle in which material is removed from a substrate. An etching cycle can be performed by plasma etching, as an example.

The term “time-based metrology data” generally represents data corresponding to measurements of different properties of an object that are measured over a time period.

The term “trained machine-learning model” generally represents a computer program that has been trained on a data set to find certain patterns or outputs based on certain inputs. Training can involve, for example, adjusting weights between nodes in a neural network using an algorithm such as backpropagation.

The term “view port” generally represents an optically translucent or transparent window through which an interior of a processing chamber can be observed.

As mentioned above, semiconductor device fabrication includes many individual steps of material deposition, patterning, and removal. Both during process development and when running control checks in production, metrology data can be collected and analyzed between process steps to monitor the process. Such metrology data often is obtained using offline techniques. Examples include scanning electron microscope (SEM) imaging of cross-sections of substrates, ellipsometry, and Fourier transform infrared spectroscopy (FTTR).

The process of obtaining metrology data for a substrate can take at least 2-3 hours per substrate in some instances. During this time, production may be stopped to ensure that the production process is operating within specification requirements. Such a stoppage in production reduces the overall output of the production process. Additionally, some measurement processes are destructive, and thus reduce overall production yield. Further, when out-of-specification substrates are discovered, extensive effort can be required to discover the root cause of the deviation. Also, multiple substrates may have been processed before the problem is discovered. This can require the substrates to be scrapped.

In contrast with offline (“ex-situ”) metrology, in-situ metrology can be used to efficiently measure a greater number of substrates, and potentially every substrate that is processed. In-situ metrology refers to metrology performed on a substrate while the substrate is in a processing tool.

In cases in which metrology is performed for a quality control process, one challenge is making sufficient measurements to ensure that the processing tool is working within specification limits. For example, it can be difficult to monitor multiple substrate parameters using the data available in current in-situ metrology methods. Performing metrology in a tool that utilizes a plasma for processing can pose particular challenges, as the energy of the plasma can interfere with measurements. Example tools that utilize plasmas are plasma deposition tools and plasma etch tools. Example plasma deposition tools are plasma-enhanced atomic layer deposition (PEALD) tools and plasma-enhanced CVD (PECVD) tools.

Accordingly, examples are disclosed that relate to performing in-situ metrology in a substrate processing tool using hyperspectral imaging of a processing chamber. Briefly, a processing tool can comprise a processing chamber comprising an optical interface, and a hyperspectral camera arranged to capture hyperspectral images of the processing chamber through the optical interface. The hyperspectral images comprise image data of the processing chamber at a plurality of different wavelengths of light. Each wavelength of light can potentially provide different information than other wavelengths of light. This can provide more data than other in-situ measurement methods. Further, the hyperspectral images can be acquired in-situ during a substrate processing cycle. This allows the computing system to characterize the substrate in real-time while the substrate is in the processing chamber, during processing or immediately after processing. In some such examples, in-situ process control can be performed by adjusting one or more control parameters of one or more processes during the substrate processing cycle based at least on the acquired metrology data. Such in-situ process control allows for a substrate to be characterized in terms of quality in real-time without destroying the substrate and without stopping the substrate processing cycle. In this way, the in-situ process control provides the technical benefits of increasing substrate quality and substrate processing throughput while decreasing cost.

In some examples, time-based metrology data can be produced from a series of hyperspectral images captured during a substrate processing cycle. The time-based metrology data includes hyperspectral imaging-based metrology measurements taken multiple times throughout the substrate processing cycle. The time-based metrology data can be used to build time-based models of properties including film growth dynamics (e.g., nucleation delays, growth based on different process steps, etc.). Further, process control can be performed by adjusting one or more control parameters of one or more processes during a substrate processing cycle based at least on the time-based metrology data and/or the time-based models. This can help to improve substrate yield compared to not using time-based metrology.

Further, in some examples, metrology-based analysis also can be performed “ex-situ” in-line between substrate processing cycles. With ex-situ in-line metrology capabilities based on hyperspectral imagery, it can be determined whether a process is operating within specification requirements. Changes then can be made for run-to-run process control. This can help to avoid tool downtime compared to acquiring metrology data using SEM or other ex-situ, destructive or non-destructive techniques.

In some examples, a computing system is configured to execute a trained machine-learning model to analyze the hyperspectral image data. The trained machine-learning model is configured to receive one or more hyperspectral images from the hyperspectral camera and output metrology data for the processing chamber based at least on the one or more hyperspectral images. The computing system further can be configured to control operation of the processing tool based at least on the metrology data.

The machine-learning model can use the time and spectral signature to predict electrical and optical properties in a film of interest. Further, image data from different spectral bands can be particularly relevant for different properties of the film being measured. For example, infrared imaging can correlate temperature response to metrics such as film thickness, non-uniformity, refractive index, resistivity, stress, and particle/defect concentrations.

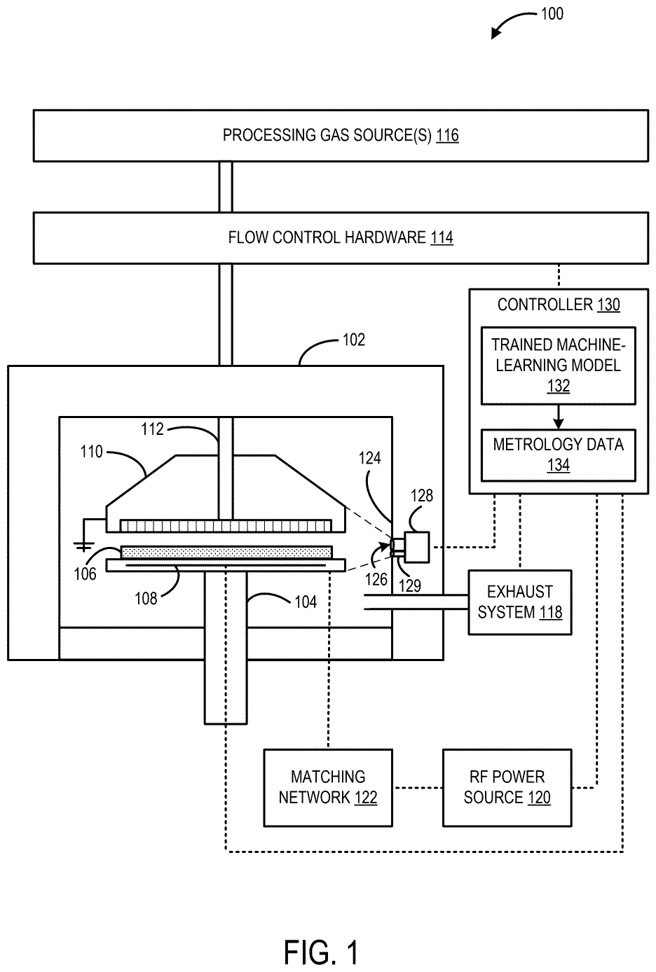

FIG. 1 shows a schematic view of an example processing tool 100. The processing tool 100 comprises a processing chamber 102 and a pedestal 104 within the processing chamber. Pedestal 104 is configured to support a substrate 106 disposed within processing chamber 102. Pedestal 104 can include a substrate heater 108. In other examples, a heater can be omitted, or can be located elsewhere within processing chamber 102.

The processing tool 100 further comprises a showerhead 110, a gas inlet 112, and flow control hardware 114. In other examples, a processing tool can comprise a nozzle or other apparatus for supplying gas into the processing chamber 102, as opposed to or in addition to a showerhead. Flow control hardware 114 is connected to one or more processing gas source(s) 116. Where processing tool 100 comprises a deposition tool, the processing gas source(s) 116 can comprise one or more precursor sources and an inert gas source to use as a diluent and/or purge gas, for example. Where processing tool 100 comprises an etching tool, CVD tool, the processing gas source(s) 116 can comprise one or more etchant gas sources and one or more inert gas sources, for example.

Flow control hardware 114 can be controlled to flow gas from processing gas source(s) into processing chamber 102 via the gas inlet 112. Flow control hardware 114 can comprise one or more flow controllers (e.g. mass flow controllers), valves, conduits, and other hardware to place a selected gas source or selected gas sources in fluid connection with gas inlet 112. In other examples, a processing chamber can comprise one or more additional gas inlets.

The processing tool 100 further comprises an exhaust system 118. The exhaust system 118 is configured to receive gases outflowing from the processing chamber 102. In some examples, the exhaust system 118 is configured to actively remove gas from the processing chamber 102 and/or apply a partial vacuum. The exhaust system 118 can comprise any suitable hardware, including one or pumps.

The processing tool 100 further comprises an RF power source 120 that is electrically connected to the pedestal 104. The RF power source 120 is configured to form a plasma. The plasma can be used to form reactive species, such as radicals, in a film deposition or etching process. The showerhead 110 is configured as a grounded opposing electrode in this example. In other examples, the RF power source 120 can supply RF power to the showerhead 110, or to other suitable electrode structure. The processing tool 100 includes a matching network 122 for impedance matching of the RF power source 120. The RF power source 120 can be configured for any suitable frequency and power. Examples of suitable frequencies include frequencies within a range of 300 kHz to 90 MHz. More specific examples of suitable frequencies include 400 kHz, 13.56 MHz, 27 MHz, 60 MHz, 90 MHz, and 2.45 GHz. Examples of suitable powers include powers between 0 and 15 kilowatts. In some examples, the RF power source 120 is configured to operate at a plurality of different frequencies and/or powers. In other examples, a processing tool alternatively or additionally can comprise a remote plasma generator (not shown). A remote plasma generator can be used to generate a plasma away from a substrate being processed.

The processing chamber 102 further comprises an optical interface 126 disposed on a sidewall 124 of the processing chamber. In other examples, the optical interface can be disposed on a different surface, such as a ceiling or a floor of the processing chamber. The optical interface 126 is an interface that can pass desired wavelength bands of electromagnetic radiation from an interior of the processing chamber to a hyperspectral camera locate external to the processing chamber while preventing the passage of gases. In the depicted example, the optical interface comprises an optically transparent window positioned in an aperture formed in the sidewall of the processing chamber. In other examples, an optical interface can be configured as a window in a top wall or bottom wall of the processing chamber. A window in the wall of the processing chamber can be configured as a view port. The term “view port” generally represents an optically transparent window in a processing chamber wall configured to allow an operator to view an interior of the processing chamber during a process. As described below, in further examples, an optical interface can comprise an optically transparent surface located on a component within the processing chamber. Example components include a pedestal and a showerhead.

The processing tool 100 also comprises a hyperspectral camera 128 arranged to capture hyperspectral images of an interior of the processing chamber 102 through the optical interface 126 of the processing chamber 102. The processing tool 100 can include any suitable number of hyperspectral cameras to capture hyperspectral images of the processing chamber 102 and/or the substrate 106. In some implementations, the processing tool can include a plurality of processing chambers/processing stations, and the processing tool can include one or more hyperspectral cameras arranged to capture hyperspectral images of some or all of the plurality of processing chambers/processing stations.

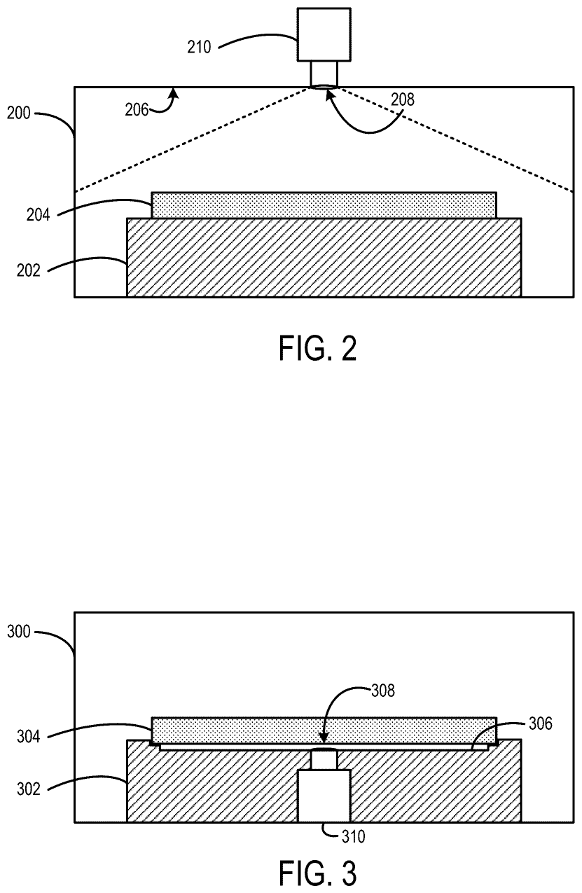

An optical interface for hyperspectral imaging of a processing chamber can be situated at any suitable location in the processing chamber. FIGS. 2-7 schematically show different example arrangements of a hyperspectral camera and optical interface(s) for imaging a processing chamber.

First, FIG. 2 shows an example processing chamber 200 including a pedestal 202 on which a substrate 204 is positioned. The processing chamber includes an optical interface 208 disposed on a top plate 206 of the processing chamber 200. A hyperspectral camera 210 is arranged to capture hyperspectral images of the substrate 204 through the optical interface 208. The optical interface 208 can be formed from any material that is suitably transparent to electromagnetic energy bands being imaged and that is suitably impermeable to processing gases. Example electromagnetic energy bands include ultraviolet, visible, and infrared bands. Example materials for optical interface 208 include fused quartz, fused silica, sapphire, a window with a coating to reduce reflection, a window with a coating to prevent degradation, and a window with a coating to reduce the impact of material being deposited on the window. In this example, the optical interface 208 is configured as a view port through which hyperspectral camera 210 can directly image the substrate 204. In the depicted example, hyperspectral camera 210 is positioned to image substrate 204 through the optical interface. In other examples, hyperspectral camera 210 can be positioned to image any other suitable structure within processing chamber 200 through the optical interface. The hyperspectral camera 210 can comprise any suitable lenses and/or other optical elements to allow a desired field of view (FOV) to be imaged.

FIG. 3 shows another example processing chamber 300. Processing chamber 300 includes a pedestal 302 on which a substrate 304 is positioned. Pedestal 302 is configured for backside processing. In such processing, a pedestal-facing side of the substrate 304 is exposed to processing gases using one or more processing gas outlets (not shown) in pedestal 302. Here, an optical interface 308 is disposed on a surface 306 of the pedestal 302. The optical interface 308 comprises an optically transparent structure through which a hyperspectral camera 310 can capture hyperspectral images of the processing chamber 300 and/or the substrate 304. For example, images of the processing chamber 300 can be acquired during a processing chamber cleaning process, when the substrate 304 is not present. Alternatively or additionally, images of a backside of the substrate 304 can be acquired during backside processing of the substrate. The hyperspectral camera 310 can include any suitable optical element(s) for imaging a desired portion of the substrate 304 and/or the processing chamber 300. Additionally or alternatively any suitable optical element(s) may be positioned intermediate the hyperspectral camera 310 and the processing chamber 300 for imaging a desired portion of the substrate 304 and/or the processing chamber 300. In some examples, a pedestal not configured for backside processing also can comprise an optical interface for hyperspectral imaging. Such a pedestal optical interface can be used, for example, to perform hyperspectral imaging metrology during a processing chamber cleaning process.

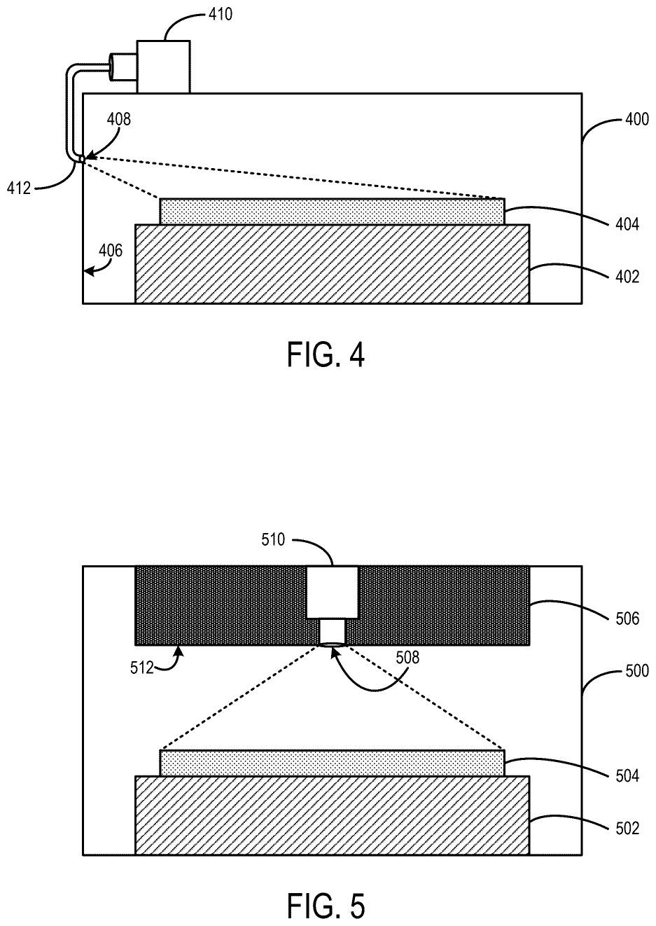

FIG. 4 shows another example processing chamber 400. Processing chamber 400 includes a pedestal 402 on which a substrate 404 is positioned. The processing chamber 400 includes an optical interface 408 disposed on the sidewall 406. The optical interface 408 comprises an optically transparent structure through which a hyperspectral camera 410 is positioned to capture hyperspectral images of the processing chamber 400 and/or the substrate 404. The hyperspectral camera 410 is arranged outside of the processing chamber 400 at a location remote from the optical interface 408. Further, an optical element 412 is arranged between the optical interface 408 and the hyperspectral camera 410. The optical element 412 is configured to direct electromagnetic radiation passing through the optical interface 408 to the hyperspectral camera 410. In this manner, the hyperspectral camera 410 captures hyperspectral images of the processing chamber 200 and/or the substrate 404 through the optical element 412. The optical element 412 is depicted as an optical fiber or other waveguide. However, the optical element 412 is representative of any one or more optical elements that can collectively direct electromagnetic radiation passing through the optical interface 408 to the hyperspectral camera 410. Example optical elements include an optical fiber, a bundle of optical fibers, another optical waveguide, one or more refractive/diffractive lenses, refractive/diffractive mirrors, waveguides, and/or filters such as polarizers. In some examples, one or more optical elements can have an adjustable optical power. This can help to focus different wavelengths of electromagnetic radiation onto an image sensor of the hyperspectral camera 410.

In some examples, the hyperspectral camera 410 can be calibrated to accommodate for the grazing angle of the optical interface 408 relative to the substrate 404. For example, distortion correction transformations can be applied to hyperspectral images captured by the hyperspectral camera 410 to accommodate for a grazing angle based upon a calibrated position of the hyperspectral camera 410.

FIG. 5 shows another example processing chamber 500. Processing chamber 500 includes a pedestal 502 on which a substrate 504 is positioned. The processing chamber 500 further comprises a showerhead 506 situated opposite the pedestal 502. The showerhead 506 comprises an optical interface 508 disposed on a surface 512 of the showerhead 506. The optical interface 508 comprises an optically transparent structure through which a hyperspectral camera 510 can capture hyperspectral images of the processing chamber 500 and/or the substrate 504.

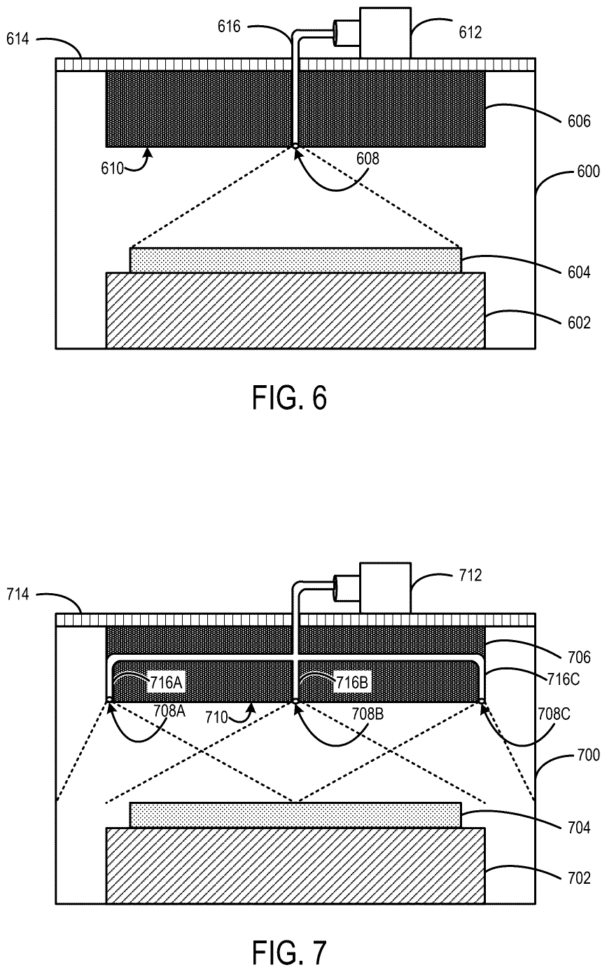

FIG. 6 shows another example processing chamber 600. Processing chamber 600 including a pedestal 602 on which a substrate 604 is positioned. The processing chamber 600 further comprises a showerhead 606 opposite the pedestal 602. An optical interface 608 is disposed on a surface 610 of the showerhead 606. The optical interface 608 comprises an optically transparent structure through which a hyperspectral camera 612 can capture hyperspectral images of the processing chamber 600 and/or the substrate 604. An optical element 616 is arranged between the optical interface 608 and the hyperspectral camera 612. The optical element 616 is configured to direct electromagnetic radiation from the optical interface 608 through the showerhead 606 to the hyperspectral camera 612. Thus, the hyperspectral camera 612 captures hyperspectral images of the processing chamber 600 and/or the substrate 604 through the optical element 616. In some examples, the optical element 616 comprises an optical fiber, or a bundle of optical fibers. Other optical elements also can be used. Examples include one or more refractive or diffractive lenses and/or mirrors.

FIG. 7 shows another example processing chamber 700. Processing chamber 700 includes a pedestal 702 on which a substrate 704 is positioned. The processing chamber 700 further comprises a showerhead 706 situated opposite the pedestal 702. A plurality of optical interfaces 708A, 708B, 708C are disposed on a surface 710 of the showerhead 706. Each optical interface 708A, 708B, 708C comprises an optically transparent structure through which a hyperspectral camera 712 can capture hyperspectral images of the processing chamber 700 and/or the substrate 704. The hyperspectral camera 712 is arranged at a location remote from the optical interfaces 708A, 708B, 708C. Here, the hyperspectral camera 712 is located on a top plate 714 of the processing chamber 700. In other examples, the hyperspectral camera can be positioned at any other suitable location.

A plurality of optical elements 716A, 716B, 716C are arranged between corresponding optical interfaces 708A, 708B, 708C and the hyperspectral camera 712. The optical elements 716A, 716B, 716C are configured to direct electromagnetic radiation passing through the plurality of optical interfaces 708A, 708B, 708C through the showerhead 706 to the hyperspectral camera 712. In the depicted example, the optical elements 716A, 716B, 716C each comprises an optical fiber, a bundle of optical fibers, or other optical waveguide or system of waveguides. Other optical elements, such as one or more refractive or diffractive lenses and/or mirrors, alternatively or additionally can be used. The plurality of optical interfaces 708A, 708B, 708C can be disposed on the surface 710 of the showerhead 706 in any suitable arrangement to collectively capture hyperspectral images of the processing chamber 700 and/or the substrate 704. Three optical interfaces 708A, 708B, 708C are shown in FIG. 7. In other examples any other suitable number of optical interfaces and associated optical elements can be used.

In some examples, the hyperspectral camera 712 is configured to capture images from optical elements 716A, 716B, 716C at spatially separate areas on an image sensor of the hyperspectral camera 712. In other examples, the hyperspectral camera 712 is configured to stitch together images collected from the plurality of optical elements 716A, 716B, 716C for reconstruction into a spatially continuous hyperspectral image of the processing chamber 700 and/or the substrate 704. In other examples, images from optical elements 716A, 716B, 716C are directed onto an image sensor of the hyperspectral camera in a partially or fully overlapping manner. In such examples, the overlapping images from optical elements 716A, 716B, 716C can be analyzed using a trained machine-learning function. Example machine-learning functions are described in more detail below.

The above-described arrangements are provided as non-limiting examples. A hyperspectral camera can be arranged in any suitable manner to capture images of a processing chamber and/or a substrate in a processing chamber.

Returning to FIG. 1, the hyperspectral camera 128 is configured to capture a hyperspectral image including a plurality of sub-images, each corresponding to a different wavelength or wavelength band. In some examples, the hyperspectral camera 128 is configured to capture a hyperspectral image including sub-images corresponding to a plurality of different wavelength bands in a range from 250 to 1000 nanometers. In other examples, wavelengths outside of this range alternatively or additionally can be imaged. Further, in some examples, the hyperspectral camera 128 is configured to capture a hyperspectral image including 20 or more sub-images, each at a different wavelength or wavelength band. In other examples, a hyperspectral camera can be configured to capture fewer than 20 sub-images.

In some examples, the hyperspectral camera 128 includes a wavelength-selective filter that separates different wavelength bands for hyperspectral imaging. An example of such a filter is a diffraction grating. In some examples, the filter is tunable to select different wavelength bands. In other examples, the high-resolution filter is configured to selectively filter a plurality of fixed wavelength bands.

In some examples, the hyperspectral camera 128 includes an illumination source 129. Such an illumination source 129 can comprise a broad-spectrum illumination source that is filtered by the high-resolution filter. In other examples, the illumination source 129 can be configured to emit light at specific wavelengths of interest. In some examples where the processing chamber 102 is a plasma reactor chamber, plasma present in the plasma reactor chamber can function as an illumination source for the hyperspectral camera 128. In further examples, the hyperspectral camera 128 can capture hyperspectral images without an illumination source. In such examples, the hyperspectral camera 128 and instead can rely on heat present in the processing chamber 102 to provide thermal-based hyperspectral data.

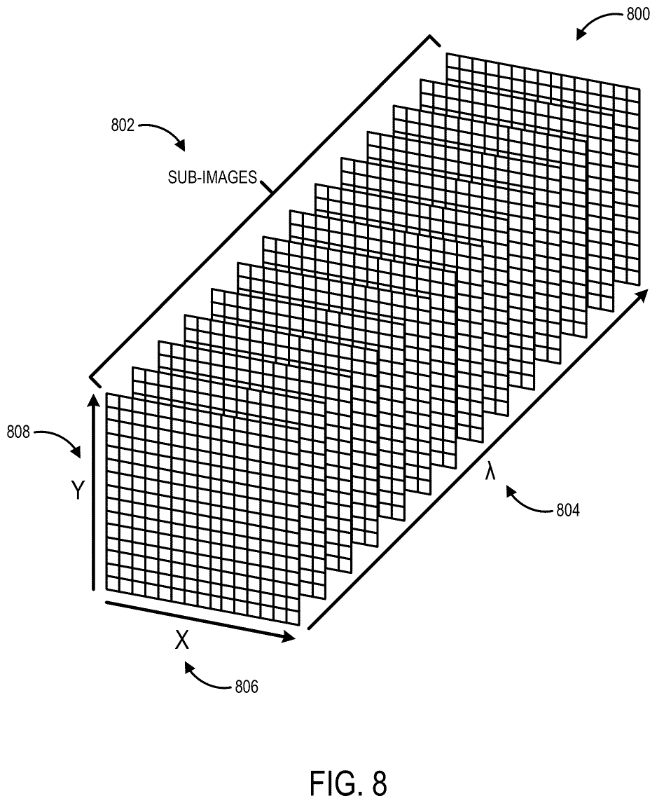

FIG. 8 schematically shows an example hyperspectral image 800 captured by a hyperspectral camera, such as the hyperspectral camera 128 shown in FIG. 1. The hyperspectral image 800 includes a plurality of sub-images 802 corresponding to different wavelength bands (A) of the electromagnetic spectrum. Each sub-image includes a plurality of pixels 804. Each pixel of a sub-image has a position defined by an X-axis 806 and a Y-axis 808, and an intensity value at a wavelength (λ) associated with the wavelength band of the sub-image. Each pixel of the hyperspectral image 800 comprises a set of spatially-mapped hyperspectral data, the set comprising an intensity datum for each sub-image. An additional dimension (e.g., an index/timestep) can be added when multiple hyperspectral images are captured over a time period. Such a time dimension allows for time-related responses of the processing chamber and/or the substrate to processing conditions to be tracked. The hyperspectral data indicates spectral signatures of different elements or materials imaged by the hyperspectral image 800. The hyperspectral data of the hyperspectral image 800 is processed to generate metrology data. Example metrology data can include measurements of thickness, non-uniformity, stress, particles FTIR spectroscopy, absorption, reflectance, and/or fluorescence spectrum data for a substrate (or one or more layers of the substrate) or processing chamber at each pixel 804 of the hyperspectral image 800.

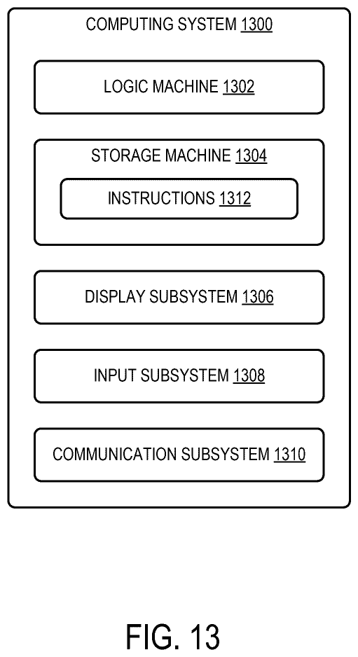

Returning to FIG. 1, a controller 130 is operatively coupled to the substrate heater 108, the flow control hardware 114, the exhaust system 118, the RF power source 120, and the hyperspectral camera 128. The controller 130 can comprise any suitable computing system, examples of which are described below with reference to FIG. 13. The controller 130 is configured to control various functions of the processing tool 100 to process substrates. As one example, the controller 130 is configured to operate the substrate heater 108 to heat the substrate 106 to a desired temperature. As another example, the controller 130 is also configured to operate the flow control hardware 114 to flow a selected gas or mixture of gases at a selected rate into the processing chamber 102. As yet another example, the controller 130 is further configured to operate the exhaust system 118 to remove gases from processing chamber 102. As still yet another example, the controller 130 is further configured to operate the flow control hardware 114 and the exhaust system 118 to control a pressure within the processing chamber 102. As another example, the controller 130 is configured to operate the RF power source 120 to form a plasma.

The controller 130 is further configured to control the hyperspectral camera 128 to capture hyperspectral images of the processing chamber 102 and/or the substrate 106. In some examples, the hyperspectral camera 128 can employ a point-to-point, line scan, or a snapshot approach to capture a hyperspectral image. In a point-to-point approach, the hyperspectral camera 128 is configured to capture hyperspectral data for a plurality of wavelength bands one pixel at a time. In a line scan approach, the hyperspectral camera 128 is configured to capture hyperspectral data for a plurality of wavelength bands one line (e.g. one row at a time). In a snapshot approach, the hyperspectral camera 128 is configured to capture an image sub-frame for each of the plurality of wavelength bands one at a time. In some examples, the controller 130 controls the hyperspectral camera 128 to capture hyperspectral images during a substrate processing cycle when a substrate is being processed. In some examples, the controller 130 controls the hyperspectral camera 128 to capture a series of hyperspectral images throughout a substrate processing cycle to track the progress of the substrate as it is being processed.

In some examples, the controller 130 can control the illumination source 129 of the hyperspectral camera 128 to output light to illuminate the substrate 106 or processing chamber 102 during image acquisition. In other examples, the controller 130 can control the hyperspectral camera 128 to acquire images while controlling the RF power source 120 to form a plasma. In such examples, the plasma can provide suitably broad-spectrum light for hyperspectral imaging. Further, in some examples, the controller 130 controls the hyperspectral camera 128 to capture hyperspectral images once a substrate processing cycle is completed. The controller 130 can control the hyperspectral camera 128 to capture any suitable number of hyperspectral images according to any suitable frame rate during and/or after a substrate processing cycle.

In some examples, the controller 130 is configured to execute a trained machine-learning model 132. The trained machine-learning model 132 is configured to receive one or more hyperspectral images from the hyperspectral camera 128 and output metrology data 134 for the processing chamber 102 and/or the substrate 106 based at least on the one or more hyperspectral images. The metrology data 134 may characterize various properties of the processing chamber 102 and/or the substrate 106. In some examples, the metrology data 134 comprises absorption, reflectance, and/or fluorescence spectrum data of the substrate 106 (and/or other materials in the processing chamber 102). Alternatively or additionally, in some examples, the metrology data 134 comprises a measurement of stress exerted on the substrate 106. Alternatively or additionally, in some examples, the metrology data 134 comprises a measurement of resistivity of the substrate 106. Alternatively or additionally, in some examples, the metrology data 134 comprises a measurement of thickness the substrate 106 and/or a thickness of individual layers deposited on the substrate 106. Alternatively or additionally, in some examples, the metrology data 134 comprises an assessment of non-uniformity of the substrate 106. Alternatively or additionally, in some examples, the metrology data 134 comprises an indication of particle detection in the processing chamber 102 and/or a measurement of a size of particles detected in the processing chamber 102. The metrology data 134 generated based at least on the hyperspectral image(s) can in some examples measure a property of the substrate 106 and/or processing chamber 102 with a greater resolution than other ex-situ metrology analysis methods that are not based on hyperspectral imagery.

In some implementations, the trained machine-learning model 132 is configured to receive a series of hyperspectral images from the hyperspectral camera 128 over a time period and output time-based metrology data 134 for the processing chamber 102 and/or the substrate 106 based at least on the series of hyperspectral images. In some examples, the series of hyperspectral images are captured during a substrate processing cycle for in-situ analysis and control of the processing tool 100. In some such examples, the series of hyperspectral images are captured during a time period that starts prior to the beginning of a substrate processing cycle and ends subsequent to completion of the substrate processing cycle. In other examples, the series of hyperspectral images are captured over a time segment that spans only a portion of a substrate processing cycle. In further examples, the series of hyperspectral images are captured over a longer time period that encompasses multiple substrate processing cycles.

The trained machine-learning model 132 can be a time-based model trained to analyze changes in metrology data to determine how the processing chamber 102 and/or the substrate 106 changes over time. The time-based metrology data 134 can track changes of any suitable type of measurement over time. As one example, the time-based metrology data 134 can track growth of a film being deposited on substrate 106 over time. As another example, the time-based metrology data 134 can measure a nucleation delay at the start of a process. As a further example, the time-based metrology data 134 can measure the efficacy of an inhibition process to control conformality. As another example, the time-based metrology data 134 can monitor progress of an etching process. As a further example, the time-based metrology data can monitor particulate contamination of a substrate during a process. As yet another example, the time-based metrology data 134 can monitor a build-up of material on a surface of the processing chamber 102. As yet another example, the time-based metrology data 134 can monitor non-uniformity of a film being deposited on substrate 106 overtime. Traditionally, a non-uniformity metric, for example of thickness, is done offline using ellipsometry or XRF or other methods on few points, such as between 10 and 50 points. Such points are used as locations in mapping the thickness, refractive index, sheet resistance, or other property to determine a non-uniformity across a full 300 mm wafer. However, using hyperspectral imagery, a more detailed mapping can be achieved. For example, depending on the resolution of the hyperspectral camera, a measurement with a resolution of smaller than 1 mm could be obtained across a 300 mm wafer using a time-based model. In this manner, not only can thickness (or other property) evolution per point be obtained, but non-uniformity evolution at a higher resolution that ex-situ measurement at the end state.

The trained machine-learning model 132 can employ any suitable method of processing time-based metrology data 134. For example, the trained machine-learning model 132 can use one or more convolutional neural networks (e.g., such as spatial and/or temporal convolutional neural networks for processing images and/or videos), recurrent neural networks (e.g., long short-term memory networks), support vector machines, associative memories (e.g., lookup tables, hash tables, Bloom Filters, Neural Turing Machine and/or Neural Random Access Memory), unsupervised spatial and/or clustering methods (e.g., nearest neighbor algorithms, topological data analysis, and/or k-means clustering), linear and/or gaussian regression modeling, graphical models (e.g., Markov models, conditional random fields, and/or AI knowledge bases), and/or other methods for dimensionality reduction and modeling.

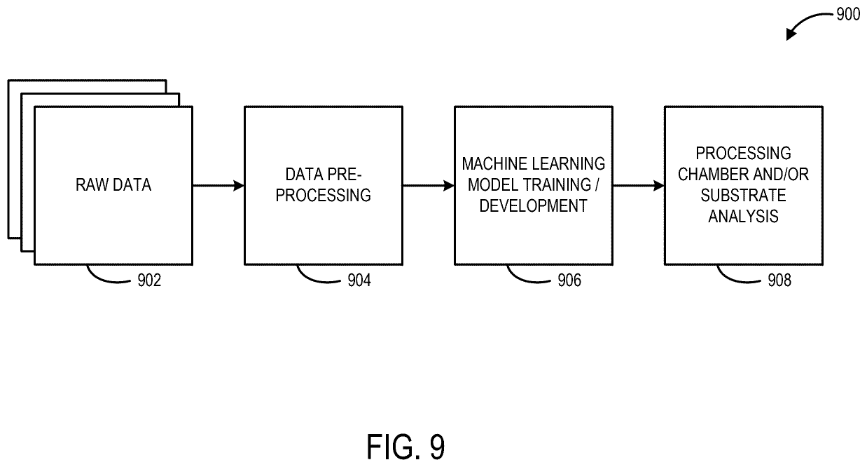

FIG. 9 shows a flow diagram depicting an example method 900 of training and executing a machine-learning model to perform metrology-based analysis on a processing chamber and/or a substrate in a processing chamber. For example, the method can be performed to train and execute the trained machine-learning model 132 shown in FIG. 1. In some examples, the controller 130 shown in FIG. 1 can perform the method. In other examples, a separate computing system can train the trained machine-learning model 132 and the controller 130 can execute the trained machine-learning model 132.

At 902, the method 900 includes receiving raw data for training the machine-learning model. In some examples, the raw data includes hyperspectral images of a processing chamber under different conditions/states. For example, when training a machine-learning model to monitor a processing chamber cleaning process, such conditions/states can include a clean processing chamber and the processing chamber with different levels of residue build-up after undergoing various numbers of processing cycles. In other examples, the raw data includes hyperspectral images of a substrate under different conditions/states to train the machine-learning function to monitor substrate processing. For example, such conditions/states can include an unprocessed substrate, substrates at different points within a process and a substrate after undergoing different processes. The raw data can include any suitable type of training data to train the machine-learning model to output metrology data based on one or more hyperspectral images. In some examples, the raw data includes metadata associated with hyperspectral camera properties. Example hyperspectral camera properties include intrinsic and extrinsic properties of the hyperspectral camera. Example intrinsic camera properties can include focal length, principal point, pixel dimensions, and pixel resolution, among other properties. Example extrinsic camera properties can include a position and orientation of the camera in world space, among other properties. In some examples, the raw data includes metadata associated with process chamber operation. Example process chamber operation properties include information such as one or more processing gases in the processing chamber, a flow rate of each of one or more processing gases, a total chamber pressure, a plasma power level, a plasma frequency, and a substrate temperature. By considering such metadata, the machine-learning models can be updated/re-trained based on changes to hardware and/or processes to be more robust and accurate under different operating conditions relative to other machine-learning models that are not updated/re-trained.

At 904, the method 900 includes pre-processing the raw data by filtering out undesired data for training of the machine-learning model. In some examples, filtered data includes duplicate hyperspectral images. In some examples, filtered data includes hyperspectral data in wavelength bands that are not of interest. For example, if the machine-learning model is being trained to process a certain film that only reacts to certain wavelength bands, then hyperspectral data corresponding to other wavelength bands to which the film does not react can be filtered out of being processed. In other examples, the raw data is pre-processed with normalization and dimensionality reduction techniques, such as principal component analysis. The pre-processing step optionally can be performed to reduce the overall time to train the machine-learning model.

At 906, the method 900 includes training/developing the machine-learning model. The machine-learning model can be trained/developed according to any suitable training procedure. Non-limiting examples of training procedures for the machine-learning model include supervised training (e.g., using gradient descent or any other suitable optimization method), zero-shot, few-shot, and unsupervised learning methods (e.g., classification based on classes derived from unsupervised clustering methods), reinforcement learning (e.g., deep Q learning based on feedback). In some examples, training can be performed by backpropagation using a suitable loss function. Example loss functions that can be used for training include mean absolute error, mean squared error, cross-entropy, Huber Loss, or other loss functions.

In some examples, the machine-learning model can be trained via supervised training on labeled training data comprising a set of images having the same structure as an input image(s). In other words, the training data comprises the same type of hyperspectral images as the hyperspectral images captured by the hyperspectral camera that are provided as input to the trained machine-learning model. For example, raw data or preprocessed data of a substrate and/or a processing chamber under different processing conditions.

At 908, the method 900 includes executing the machine-learning model to perform metrology-based analysis on a processing chamber of a processing tool and/or a substrate in the processing chamber. In particular, the machine-learning model receives one or more hyperspectral images of the processing chamber and/or the substrate as input and outputs metrology data based on the one or more hyperspectral images.

In some examples, metrology data representing one or more of observable properties of a processing chamber and/or substrate can be used for calibration and verification of a hyperspectral metrology machine-learning model. As one example, film thickness on a substrate can be observed to determine whether a deposition process is operating within specifications based on control suggested by a trained machine-learning model. If the film thickness is within specifications, then the controller can verify that the trained machine-learning model is operating appropriately. Otherwise, if the film thickness is outside of the specifications, then the trained machine-learning model can be adjusted/re-calibrated to adjust control of the deposition process such that the film thickness is within the specifications. Metrology data may be used to verify and/or calibrate the trained machine-learning model in any suitable manner.

Returning to FIG. 1, the controller 130 is configured to adjust control of the processing tool 100 based at least on the metrology data 134 output by the trained machine-learning model 132. In some examples, the trained machine-learning model 132 is configured to output recommended control adjustments based on the metrology data 134. In other examples, a separate trained machine-learning model can be configured to recommend certain control adjustments based at least on the metrology data 134. In still other examples, the controller 130 can include separate logic that is configured to adjust control of the processing tool 100 based at least on the metrology data 134. In still other examples, the controller 130 is configured to visually present the metrology data 134 via a display to a human operator, and the controller 130 is configured to adjust operation of the processing tool 100 based at least on user input received from the human operator.

In some examples, the controller 130 is configured to adjust operation of the processing tool 100 based on the metrology data 134 for the processing chamber 102 itself. The controller 130 can be configured to adjust any suitable control parameter of any suitable process performed by the processing tool 100 based on the metrology data 134 for the processing substrate.

As mentioned above, in some examples, the controller 130 can be configured to adjust a control parameter of a cleaning process to clean the processing chamber 102 based at least on the metrology data 134 for the processing chamber 102. In one example, the metrology data 134 for the processing chamber 102 can indicate an amount of material built up on the interior of the processing chamber 102, and the controller 130 can be configured to determine whether the amount of material built up on the interior of the processing chamber 102 is greater than a threshold amount. If the amount of material is greater than the threshold amount, the controller 130 initiates a cleaning process. Additionally or alternatively, the controller 130 can monitor progress of a cleaning process based on the amount of material built up on the interior of the processing chamber 102 for endpoint detection. By intelligently controlling the cleaning process based on the metrology data 134 for the processing chamber 102, cleaning of the processing chamber can be performed more efficiently, and as needed. This can provide for reduced tool maintenance time relative to a cleaning process that is performed according to a fixed frequency or for a fixed length/extent.

Alternatively or additionally, in some examples, the controller 130 can be configured to perform in-situ analysis of metrology data that is collected during a substrate processing cycle and adjust control of the processing tool in real time during the substrate processing cycle.

In some such examples, the controller 130 can be configured to monitor particle contamination on a substrate surface or otherwise in a processing chamber during a process based at least on the metrology data 134. Such in-situ analysis allows for intelligent scheduling of other inspection operations. This can help limit the number of substrates that are scanned on optical scattering tools for particle detection. This can also help to restrict regions of a substrate on which an analysis such as energy-dispersive X-ray (EDX) analysis is performed to determine composition of particles for troubleshooting. As another example, the controller 130 can be configured to perform in-situ analysis of time-based metrology data for a substrate that is collected during a substrate processing cycle. The controller further can be configured to adjust control of the processing tool in real time during the substrate processing cycle. The controller 130 can be configured to adjust any suitable control parameter of any suitable substrate process in real time based on in-situ analysis of time-based metrology data.

Alternatively or additionally, in some such examples, the controller 130 can be configured to track the film thickness based at least on the time-based metrology data during the film deposition process. The controller 130 further can be configured to tune the deposition process to control a deposition rate. As a more specific example, the controller 130 can be configured to allow for a high deposition growth rate until a first threshold thickness is detected. The controller can further be configured to then adjust processing conditions to reduce the deposition rate to until a desired final thickness is achieved.

Alternatively or additionally, in some such examples, in a process that utilizes an inhibitor, the controller 130 can be configured to track the efficacy of the inhibition process during the inhibition process based at least on the time-based metrology data and dynamically tune inhibition time and/or the number of inhibition cycles based on the efficacy derived from the time-based metrology data. This can help to ensure that film growth is properly inhibited according to a desired process. As an example, an inhibited ALD process can be performed by first depositing an inhibitor on a feature such that a higher concentration of inhibitor deposits on a substrate surface and a lower concentration deposits within a substrate recess. Then, ALD can be used to deposit a film such that the final film is thicker within the substrate recess and thinner or fully inhibited on the substrate surface. In such an example, hyperspectral imaging can be performed to monitor inhibitor adsorption onto the substrate surface. This can allow the inhibitor deposition to be continued until a desired level of inhibitor adsorption is reached. The hyperspectral camera also can be used to monitor film growth on the substrate surface. This can be used to determine whether the inhibitor is effectively inhibiting film growth, or whether an additional inhibitor deposition cycle is needed.

Alternatively or additionally, in some examples, the controller 130 can be configured to perform ex-situ in-line analysis of metrology data for a substrate and adjust control of the processing tool 100 between substrate processing cycles. The controller 130 can be configured to adjust any suitable control parameter of any suitable substrate process on a run-to-run basis based on ex-situ in-line analysis of the metrology data.

Ex-situ in-line measurements can be performed in various different manners. In some examples, a processing tool can comprise a separate module for hyperspectral imaging of substrates. “Separate module” as used herein refers generally to a space within a processing tool that is separate from one or more processing chambers of the processing tool, and that substrates can be moved into by substrate handling systems for hyperspectral imaging. In other examples, ex-situ in-line measurements can be performed while the substrate is being transferred into or out of a processing chamber of a processing tool. For example, the hyperspectral camera 128 may be positioned outside a slit valve through which a substrate is moved when being transferred to or from a processing station, and a substrate may be imaged by the hyperspectral camera 128 as the substrate passes through or out of the slit valve. In other examples, a substrate may be imaged for ex-situ inline hyperspectral image-based metrology analysis when the substrate is in a transfer module, a load lock module, a front opening unified pod (FOUP), or an equipment front end module (EFEM). In still other examples, a hyperspectral camera having an illumination source (e.g., tungsten quartz, Xenon, LED Set 400 nm-1000 nm) can be placed above a vacuum transfer arm that moves across a substrate and the hyperspectral camera can function as a line scan camera to image the substrate as the vacuum transfer arm moves relative to the substrate.

In some such examples, the controller 130 can be configured to compare a parameter value of interest from the metrology data 134 for a substrate to an expected/ideal parameter value. For example, the thickness of a deposited film after a deposition process cycle is completed can be measured via hyperspectral imagery and compared to a targeted thickness. If the measured thickness deviates beyond a threshold amount from the targeted thickness, the controller 130 can be configured to adjust control parameters (e.g., power, pressure, gas flow parameters) for a subsequent substrate processing cycle for a different substrate, so that accuracy of the subsequent substrate processing cycle for the different substrate is increased relative to the previous substrate processing cycle.

Alternatively or additionally in some such examples, if the controller 130 determines that a thickness of a film deposed on a substrate is outside of a threshold measure of uniformity based at least on analysis of the metrology data 134, the controller 130 can be configured to perform an auto-correction in process controls (e.g., a change in process gap, a change in spindex/index operation). In yet another example, the controller 130 is configured to trigger alerts for manual correction by a human engineer based on determining that the thickness of a film deposited on a substrate is highly non-uniform. For example, the controller 130 can trigger the performance of a showerhead-pedestal leveling process.

In some examples, the trained machine-learning model 132 is configured to generate recommendations for control adjustments for a human operator to make based on the metrology data 134.

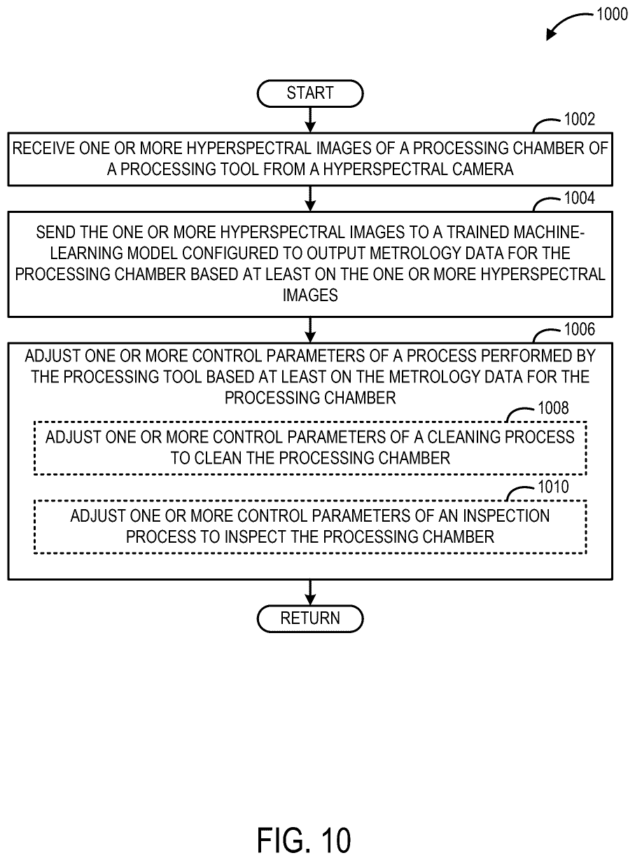

FIG. 10 shows a flow diagram depicting an example method 1000 of performing metrology-based analysis using hyperspectral images to control a cleaning process of a processing chamber. For example, the method 1000 can be performed by the controller 130 of FIG. 1.

At 1002, the method 1000 includes receiving one or more hyperspectral images of a processing chamber of a processing tool from a hyperspectral camera. At 1004, the method 1000 includes sending the one or more hyperspectral images to a trained machine-learning model configured to output metrology data for the processing chamber based at least on the one or more hyperspectral images. At 1006, the method 1000 includes adjusting one or more control parameters of a process performed by the processing tool based at least on the metrology data for the processing chamber. In some implementations, at 1008, the method 1000 optionally can include adjusting one or more control parameters of a cleaning process during cleaning of a processing chamber. In some examples, a frequency at which a cleaning process is performed and/or a length/extent of a cleaning process is adjusted based on an amount of buildup of material on the processing chamber as indicated by the metrology data for the processing chamber. Additionally or alternatively, in some examples, a cleaning pressure, a cleaning gas flow rate, and/or a cleaning gas timing may be adjusted based on analysis of the metrology data.

Alternatively or additionally, in some implementations, at 1010, the method 1000 optionally can include adjusting one or more control parameters of an inspection process to inspect the process chamber. In one example, a frequency at which an inspection process is adjusted based on detecting particles in the processing chamber as indicated by the metrology data for the processing chamber.

The method 1000 can be performed to control operation of the processing tool in an intelligent manner based on feedback provided by the metrology data for the processing chamber. Such intelligent operation can include performing cleaning and/or inspection operations only as needed as determined by the feedback. Such intelligent operation can increase efficiency and throughput of the processing tool relative to a processing tool that performs such operations without feedback. The method 1000 may be performed repeatedly for any suitable number of processes and/or processing cycles.

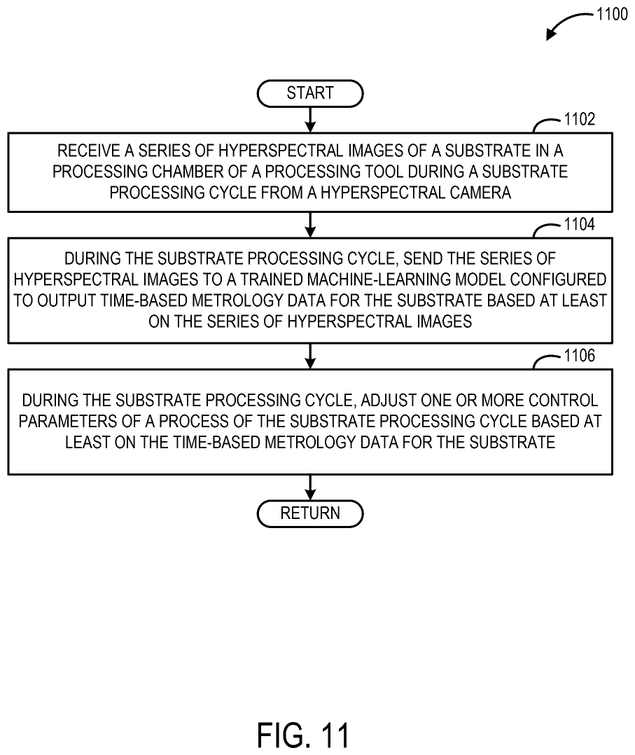

FIG. 11 shows a flow diagram depicting an example method 1100 of performing metrology-based analysis using hyperspectral images for in-situ control of a processing tool during a substrate processing cycle. For example, the method 1100 can be performed by the controller 130 shown in FIG. 1.

At 1102, the method 1100 includes receiving a series of hyperspectral images of a substrate in a processing chamber of a processing tool during a substrate processing cycle from a hyperspectral camera. At 1104, the method 1100 includes during the substrate processing cycle, sending the series of hyperspectral images to a trained machine-learning model configured to output time-based metrology data for the substrate based at least on the series of hyperspectral images. At 1106, the method 1100 includes during the substrate processing cycle, adjusting one or more control parameters of a process of the substrate processing cycle based at least on the time-based metrology data for the substrate. Examples of control parameters that can be adjusted include one or more of a process time, a substrate temperature, a showerhead temperature (where a showerhead has a heater), a spacing between a showerhead and a pedestal, a total process pressure, a partial pressure of each of one or more process gases, and a radiofrequency power. The method 1100 thereby can provide in-situ metrology-based analysis using hyperspectral images that enables real-time adjustment and control of the processing tool. In some implementations, in-situ metrology-based analysis/metrology data optionally may be tracked across different processing cycles for a plurality of substrates to adjust control of a particular process. For example, for a given process step (at a given iteration), a particular statistic/characteristic is tracked for each of a plurality of substrates to determine if there is a drift/shift occurring that can be corrected by adjustment of the process. The method 1100 may be performed repeatedly for any suitable number of processes and/or processing cycles.

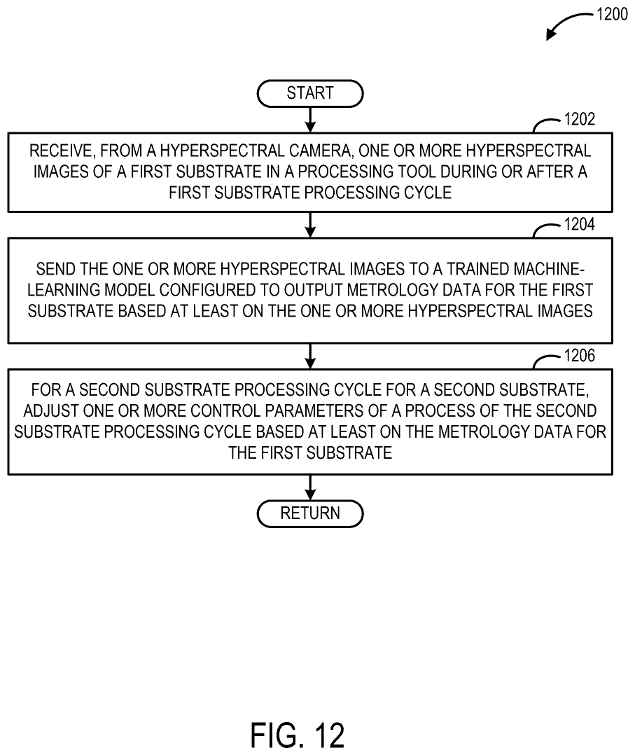

FIG. 12 shows a flow diagram depicting an example method 1200 of performing metrology-based analysis using hyperspectral images for ex-situ in-line control of a processing tool between substrate processing cycles. For example, the method 1200 can be performed by the controller 130 shown in FIG. 1. At 1202, the method 1200 includes receiving, from a hyperspectral camera, one or more hyperspectral images of a first substrate of a processing tool during or after a first substrate processing cycle. Note that the substrate may be imaged by the hyperspectral camera in any suitable processing module of the processing tool or while being transferred between different processing modules of the processing tool for ex-situ in-line metrology-based analysis. At 1204, the method 1200 includes sending the one or more hyperspectral images to a trained machine-learning model configured to output metrology data for the first substrate based at least on the one or more hyperspectral images. At 1206, the method 1200 includes, for a second substrate processing cycle for a second substrate, adjusting one or more control parameters of a process of the second substrate processing cycle based at least on the metrology data for the first substrate. The method 1200 can be performed to provide ex-situ in-line metrology-based analysis using hyperspectral images that enables adjustment and control of the processing tool on a run-to-run basis between substrate processing cycles. Further, the method 1200 can be performed to provide ex-situ in-line metrology-based analysis that occurs over multiple processing cycles of a plurality of different substrates, such as to correct for drift/shift in operation over longer periods of time.

In some embodiments, the methods and processes described herein can be tied to a computing system of one or more computing devices. In particular, such methods and processes can be implemented as a computer-application program or service, an application-programming interface (API), a library, and/or other computer-program product.

FIG. 13 schematically shows a non-limiting embodiment of a computing system 1300 that can enact one or more of the methods and processes described above. Computing system 1300 is shown in simplified form. Computing system 1300 can take the form of one or more personal computers, workstations, computers integrated with wafer processing tools, and/or network accessible server computers.

Computing system 1300 includes a logic machine 1302 and a storage machine 1304. Computing system 1300 can optionally include a display subsystem 1306, input subsystem 1308, communication subsystem 1310, and/or other components not shown in FIG. 13. The controller 130 is an example of the computing system 1300.

Logic machine 1302 includes one or more physical devices configured to execute instructions. For example, the logic machine can be configured to execute instructions that are part of one or more applications, services, programs, routines, libraries, objects, components, data structures, or other logical constructs. Such instructions can be implemented to perform a task, implement a data type, transform the state of one or more components, achieve a technical effect, or otherwise arrive at a desired result.

The logic machine can include one or more processors configured to execute software instructions. Additionally or alternatively, the logic machine can include one or more hardware or firmware logic machines configured to execute hardware or firmware instructions. Processors of the logic machine can be single-core or multi-core, and the instructions executed thereon can be configured for sequential, parallel, and/or distributed processing. Individual components of the logic machine optionally can be distributed among two or more separate devices, which can be remotely located and/or configured for coordinated processing. Aspects of the logic machine can be virtualized and executed by remotely accessible, networked computing devices configured in a cloud-computing configuration.

Storage machine 1304 includes one or more physical devices configured to hold instructions 1312 executable by the logic machine to implement the methods and processes described herein. When such methods and processes are implemented, the state of storage machine 1304 can be transformed—e.g., to hold different data.

Storage machine 1304 can include removable and/or built-in devices. Storage machine 1304 can include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine 1304 can include volatile, nonvolatile, dynamic, static, read/write, read-only, random-access, sequential-access, location-addressable, file-addressable, and/or content-addressable devices.

It will be appreciated that storage machine 1304 includes one or more physical devices. However, aspects of the instructions described herein alternatively can be propagated by a communication medium (e.g., an electromagnetic signal, an optical signal, etc.) that is not held by a physical device for a finite duration.

Aspects of logic machine 1302 and storage machine 1304 can be integrated together into one or more hardware-logic components. Such hardware-logic components can include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 1306 can be used to present a visual representation of data held by storage machine 1304. This visual representation can take the form of a graphical user interface (GUI). As the herein described methods and processes change the data held by the storage machine, and thus transform the state of the storage machine, the state of display subsystem 1306 can likewise be transformed to visually represent changes in the underlying data. Display subsystem 1306 can include one or more display devices utilizing virtually any type of technology. Such display devices can be combined with logic machine 1302 and/or storage machine 1304 in a shared enclosure, or such display devices can be peripheral display devices.

When included, input subsystem 1308 can comprise or interface with one or more user-input devices such as a keyboard, mouse, or touch screen. In some embodiments, the input subsystem can comprise or interface with selected natural user input (NUI) componentry. Such componentry can be integrated or peripheral, and the transduction and/or processing of input actions can be handled on- or off-board. Example NUI componentry can include a microphone for speech and/or voice recognition, and an infrared, color, stereoscopic, and/or depth camera for machine vision and/or gesture recognition.

When included, communication subsystem 1310 can be configured to communicatively couple computing system 1300 with one or more other computing devices. Communication subsystem 1310 can include wired and/or wireless communication devices compatible with one or more different communication protocols. As non-limiting examples, the communication subsystem can be configured for communication via a wireless telephone network, or a wired or wireless local- or wide-area network. In some embodiments, the communication subsystem can allow computing system 1300 to send and/or receive messages to and/or from other devices via a network such as the Internet.

As discussed above, with reference to FIG. 1, the controller 130 is configured to execute the trained machine-learning model 132. The trained machine-learning model 132 is configured to receive one or more hyperspectral images from the hyperspectral camera 128 and output metrology data 134 for the processing chamber 102 and/or the substrate 106 based at least on the one or more hyperspectral images. The metrology data 134 may characterize various properties of the processing chamber 102 and/or the substrate 106.

In some implementations, the machine-learning model 132 is trained to predict/identify various properties of the substrate 106 and/or other material (e.g., gases) in the processing chamber 102 based at least one the spectral signatures produced in the hyperspectral images output from the hyperspectral camera 128. Different spectral signatures are produced from different gases and substrates because different gases and substrates transmit and reflect different wavelengths and intensities of light. Further, variations in the spectral signatures captured in the hyperspectral images can be caused by variations in density of gas/plasma, composition of gas/plasma (e.g., different types of gasses transmit and reflect different wavelengths and intensities to create different spectral signatures captured in the hyperspectral images), flow path of gas/plasma during a process, composition of the substrate 106, thickness of the substrate 106 and/or the density of the substrate 106. In order to identify these properties, the hyperspectral camera 128 captures a plurality of hyperspectral images “in-situ” while the substrate is in the processing tool, and the machine-learning model 132 is trained to predict/identify these properties based at least on analyzing the plurality of hyperspectral images. The machine-learning model 132 can be trained to predict/identify any or all of these properties based at least on analyzing the plurality of hyperspectral images of the processing chamber 102 and/or the substrate 106. The machine-learning model 132 can be trained to identify any suitable properties of the processing chamber 102, the substrate 106, and/or other material in the processing chamber 102 based at least on analyzing the spectral signatures corresponding to these different elements that are captured in the plurality of hyperspectral images.

In some implementations, the controller 130 is configured to execute a plurality of machine-learning models that are each trained to predict/identify a different property of the processing chamber 102, the substrate 106, and/or other material in the processing chamber 102 based at least on analyzing the plurality of hyperspectral images. The controller 130 can execute the plurality of machine-learning models concurrently to analyze the plurality of hyperspectral images to predict/identify the different properties of the processing chamber 102, the substrate 106, and/or other material in the processing chamber 102.

In some implementations, the hyperspectral camera 128 is configured to capture a series of hyperspectral images of the substrate 106 in-situ during a process being performed on the substrate 106 in order to determine whether the process is being performed properly according to a specification or within designated tolerance levels. In one example, the machine-learning model 132 is trained to analyze differences in reflectance spectra across the substrate 106 during a process and determine whether the substrate 106 is within the specification or within the designated tolerance levels.

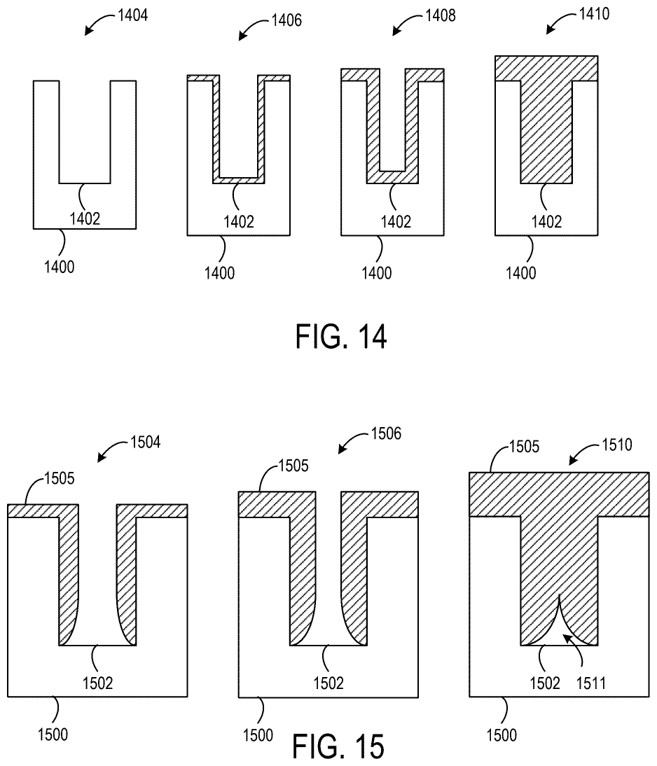

FIG. 14 schematically shows different example states of a substrate 1400 during a process in which a gap 1402 of a feature of the substrate 1400 is being filled by atomic layer deposition (ALD). ALD can provide for conformal growth of a film, such that the film has a substantially consistent thickness on all aspects. At 1404, a first state of the gap 1402 is shown in which the gap 1402 is empty. For example, the gap 1402 can assume the first state at the beginning of the process. At 1406, a second state of the gap 1402 is shown in which the gap 1402 is partially filled. At 1408, a third state of the gap 1402 is shown in which the gap 1402 is partially filled to a greater degree than in the second state. At 1410, a fourth state of the gap 1402 is shown in which the gap 1402 is completely filled. For example, the gap 1402 can assume the fourth state at the end of the process.

In some implementations, the hyperspectral camera 128 is configured to capture hyperspectral images of the substrate 1400 in each of the different states 1404-1410 during the process of filling the gap 1402. The reflectance spectra of the region in the hyperspectral images that corresponds to the substrate 1400, and more particularly the gap 1402, differs in each of the different states 1404-1410. The differences in reflectance spectra in the hyperspectral images allows for the different states of the gap 1402/substrate 1400 to be identified via analysis of the hyperspectral images. In some implementations, the machine-learning model 132 is trained with hyperspectral images that include reflectance spectra corresponding to different substrates in different states during a process (e.g., including different fill levels of gaps on a substrate), such that the trained machine-learning model 132 can identify a state of a substrate at any given point in a process based at least on analysis of hyperspectral image(s) of the substrate captured by the hyperspectral camera 128 during the process.

In some implementations, the controller 130 is configured to generate a thickness map of a substrate from a plurality of different hyperspectral images of the substrate captured at different points during the process. The thickness map provides a visual representation of film growth (or various other states of the substrate) over the course of a process. By training the machine-learning model 132 in this manner, the trained machine-learning model 132 is able to determine whether or not there are any issues with a substrate during a process and identify the type of issue if one does occur.

FIG. 15 schematically shows different example states of a substrate 1500 during a fill process in which a void forms in a gap 1502 of a feature of the substrate 1500 that is filled. At 1504, a film 1505 being deposited has tapered sidewalls near a bottom of the gap 1502. This may arise, for example, from not saturating the substrate surfaces within the gap 1502 in an ALD process. Continuing at 1506, as the film thickens, the tapered sidewalls remain. At 1510, it can be seen that a void 1511 remains after the gap fill process is complete. The gap 1502 with the void 1511 can have a different reflectance spectra in hyperspectral images compared to a gap that is filled with a void-free film.

In each of the examples described above, the issues with the substrate 1500 (or the lack of issues) are manifested as changes in the reflectance spectra in the hyperspectral images of the substrate 1500. In these examples, the machine-learning model 132 can identify the issues with the substrate 1500 based at least on analysis of hyperspectral images of the substrate 1500 captured before, during, and/or after the fill process is performed to determine the changes in reflectance spectra of the substrate 1500 before, during, and/or after the fill process is performed. The machine-learning model 132 can analyze these hyperspectral images to determine whether the process is being performed properly, and the controller 130 can dynamically adjust the process to compensate for any issues that are identified by the machine-learning model 132. Such control can be performed in-situ during a process or in between different batches of processes depending on the implementation.

In some implementations, a location of the hyperspectral camera 128 is configured to be dynamically adjustable to adjust a distance of the hyperspectral camera 128 relative to a scene/object being imaged. By varying the distance of the hyperspectral camera 128 relative to a scene/object being imaged, the field of view of the hyperspectral camera 128, and correspondingly the physical size of pixels in the hyperspectral images produced at the different distances, changes. This allows for greater control of hyperspectral measurements in regions of interest, especially in relatively small regions of interest, such as used to determine a degree of haze in a layer of a substrate, as one example. Moreover, different hyperspectral images of a scene/object captured at different distances relative to the imaged scene/object can be compared to one another in order to distinguish relevant metrology data from noise.

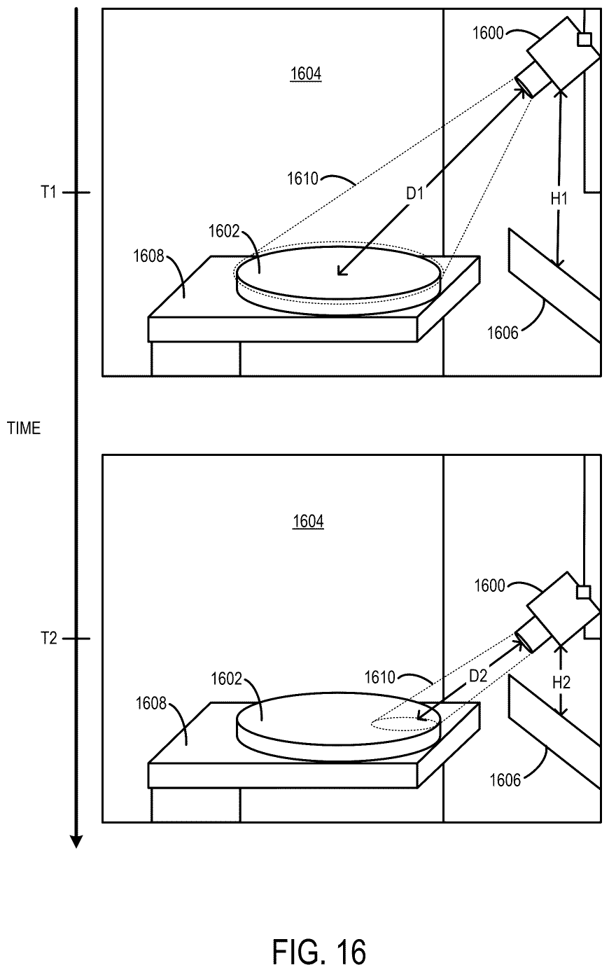

FIG. 16 schematically shows an example scenario where a hyperspectral camera 1600 is configured to be dynamically adjustable in order to adjust a distance of the hyperspectral camera 1600 relative to a substrate 1602 being imaged. The hyperspectral camera 1600 is located within a transfer module 1604 of a processing tool, such as the processing tool 100 shown in FIG. 1. In other examples, the hyperspectral camera 1600 may be located in a different portion of the processing tool, such as a processing chamber module, a load lock module, or an equipment front end module (EFEM).

The hyperspectral camera 1600 is located above a slit valve 1606 in the transfer module 1604. A robot arm 1608 holds the substrate 1602 and moves the substrate 1602 within in the transfer module 1604. The robot arm 1608 passes the substrate 1602 through the slit valve 1606 when the substrate 1602 is transferred from the transfer module 1604 to a processing module. Further, the robot arm 1608 receives the substrate 1602 from the slit valve 1606 when the substrate 1602 is transferred from the processing module to the transfer module 1604. In the illustrated example, a height of the hyperspectral camera 1600 is adjustable within the transfer module in order to adjust a distance between the hyperspectral camera 1600 and the substrate 1602. The hyperspectral camera 1600 can capture one or more hyperspectral images of the substrate 1602 from different distances as the substrate passes into or out of the slit valve 1606.

In one example, at a first time (T1), the hyperspectral camera 1600 is positioned at a first height (H1) in the transfer module 1604, such that the hyperspectral camera 1600 is a first distance (D1) from the substrate 1602. At the first distance (D1), the substrate 1602 is positioned fully within a field of view 1610 of the hyperspectral camera 1600. The hyperspectral camera 1600 captures one or more hyperspectral images of the substrate 1602 from this first position. In some examples, the hyperspectral camera 1600 is a line scan camera that scans the substrate 1602 as it pass under the hyperspectral camera 1600 into the slit valve 1606. In other examples, the hyperspectral camera 1600 is configured to take a snapshot of the entire substrate 1602 at a particular indexed location before the substrate is passed into the slit valve 1606.

At a second time (T2), the hyperspectral camera 1600 is dynamically adjusted relative to the substrate 1602. In particular, the hyperspectral camera 1600 is lowered to a second height (H2) in the transfer module 1604, such that the hyperspectral camera 1600 is a second distance (D1) from the substrate 1602 that is closer than the first distance (D1). At the second distance (D2), only a portion of the substrate 1600 is positioned within the field of view 1610 of the hyperspectral camera 1600. The hyperspectral camera 1600 captures one or more hyperspectral images of the substrate 1602 from this second position. Since the hyperspectral camera 1600 is positioned closer to the substrate 1602 in the second position than in the first position, pixels of the hyperspectral images captured by the hyperspectral camera 1600 in the second position correspond to a smaller or more granular region of the substrate 1602 relative to pixel of hyperspectral images captured when the hyperspectral camera 1600 is in the first position.

Alternatively or additionally, in some implementations, the hyperspectral camera 1600 may include one or more optical components (e.g., a zoom lens) that is configured to optically adjust a distance between an image sensor of the hyperspectral camera 1600 and the scene/object (e.g., substrate 1602) being imaged. The one or more optical components can be dynamically adjusted in order to adjust a distance of the hyperspectral camera 128 relative to a scene/object being imaged.

Alternatively or additionally, in some implementations, the substrate 1602 can be moved by the robot arm 1708 relative to the position of the hyperspectral camera 1600 to dynamically adjust a distance between the hyperspectral camera 1600 and the substrate 1602.

In some implementations, the machine-learning model 132 is trained based at least on hyperspectral images of scene(s) (e.g., processing chambers) and/or object(s) (e.g., substrates) captured at different distances relative to the hyperspectral camera that captured the hyperspectral images. The trained machine-learning model 132 can be configured to receive one or more hyperspectral images of a substrate captured at a first distance relative to the substrate and output metrology data 134 for the substrate based at least on the one or more hyperspectral images captured at the first distance. Further, the trained machine-learning model 132 can be configured to receive one or more hyperspectral images of the substrate captured at a second distance relative to the substrate that is different than the first distance and output metrology data 134 for the substrate based at least on the one or more hyperspectral images captured at the second distance. For example, the second distance may be less than the first distance. The change in distance can be performed dynamically by physically moving the hyperspectral camera or optically by adjusting an optical component of the hyperspectral camera depending on the implementation.

In some examples, the metrology data 134 for the substrate can differ in relation to the different distances of the hyperspectral camera relative to the substrate. In some examples, the hyperspectral camera 1600 is moved closer to the substrate in order to obtain metrology data 134 for a particular feature or region of interest, such as to inspect one or more gaps being filled or other features on the substrate. In other examples, the hyperspectral camera be dynamically adjusted to capture more of the substrate (e.g., the whole substrate) in the field of view of the hyperspectral camera and the machine-learning model can output metrology data 134 for the substrate based on hyperspectral images captured at that distance. In some implementations, the machine learning model 132 is configured to receive hyperspectral images of a substrate captured at different distances, compare the reflectance spectra of the different hyperspectral images to distinguish actual spectral information from noise, and output noise-filtered metrology data 134 for the substrate.

In some implementations, the hyperspectral camera 128 is configured to be dynamically adjustable in order to adjust an angle of the hyperspectral camera 128 relative to a scene/object being imaged. The angle of incidence of light emitted from the hyperspectral camera 128 on a scene/object being image can change how the light interacts with the surface(s) of the scene/object and affects the reflectance spectra. Some angles of incidence may be more optimal than others for prediction output accuracy depending on the material(s) being imaged by the hyperspectral camera 128. In some examples a set of selected angles may be optimized for a particular material.

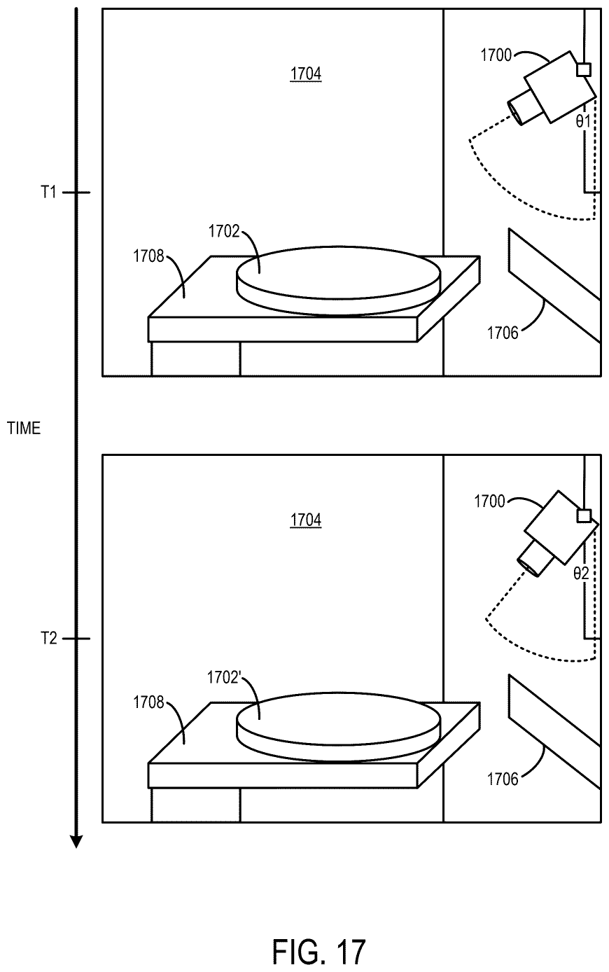

FIG. 17 schematically shows an example scenario where a hyperspectral camera 1700 is configured to be dynamically adjustable in order to adjust an angle of incidence of light emitted from the hyperspectral camera 1700 on different substrates 1702, 1702′ being imaged. The hyperspectral camera 1700 is located within a transfer module 1704 of a processing tool, such as the processing tool 100 shown in FIG. 1. In other examples, the hyperspectral camera 1700 may be located in a different portion of the processing tool, such as a processing chamber module, a load lock module, or an equipment front end module (EFEM).

The hyperspectral camera 1700 is located above a slit valve 1706 in the transfer module 1704. A robot arm 1708 holds the substrates 1702, 1702′ and moves the substrates 1702, 1702′ within the transfer module 1704. The robot arm 1708 passes the substrates 1702, 1702′ through the slit valve 1706 when the substrates 1702, 1702′ are transferred from the transfer module 1704 to a processing module. Further, the robot arm 1708 receives the substrates 1702, 1702′ from the slit valve 1706 when the substrates 1702, 1702′ are transferred from the processing module to the transfer module 1704. In the illustrated example, an angle of the hyperspectral camera 1700 is adjustable within the transfer module in order to adjust an angle of incidence of light emitted from the hyperspectral camera 1700 and onto a substrate being imaged. The hyperspectral camera 1700 can capture one or more hyperspectral images of the substrates 1702, 1702′ from different angles of incidence as the substrates 1702, 1702′ pass into or out of the slit valve 1706.

In one example, at a first time (T1), the hyperspectral camera 1700 is positioned at a first angle (θ1) relative to a first substrate 1702 having a surface film comprising a first material. For example, the first angle (θ1) may be selected based at least on being optimized for how the first material of the surface film reacts to light in different wavelengths at the selected angle of incidence. The hyperspectral camera 1700 captures one or more hyperspectral images of the substrate 1702 from this first angle (θ1). In some examples, the hyperspectral camera 1700 is a line scan camera that scans the substrate 1702 as it passes under the hyperspectral camera 1700 into the slit valve 1706. In other examples, the hyperspectral camera 1700 is configured to take a snapshot of the entire substrate 1702 at a particular indexed location before the substrate 1702 is passed into the slit valve 1706.

At a second time (T2), the hyperspectral camera 1700 is dynamically adjusted to a second angle (θ2) relative to a second substrate 1702 having a surface film comprising a second material different from the first material of the surface film of the first substrate 1702. For example, the second angle (θ2) may be selected based at least on being optimized for how the second material of the surface film reacts to light in different wavelengths at the selected angle of incidence. The hyperspectral camera 1700 captures one or more hyperspectral images of the second substrate 1702′ from this second angle (θ2).

Alternatively or additionally, in some implementations, the substrates 1702, 1702′ can be moved by the robot arm 1708 relative to the position of the hyperspectral camera 1700 to dynamically adjust an angle between the hyperspectral camera 1700 and the substrates 1702, 1702′.

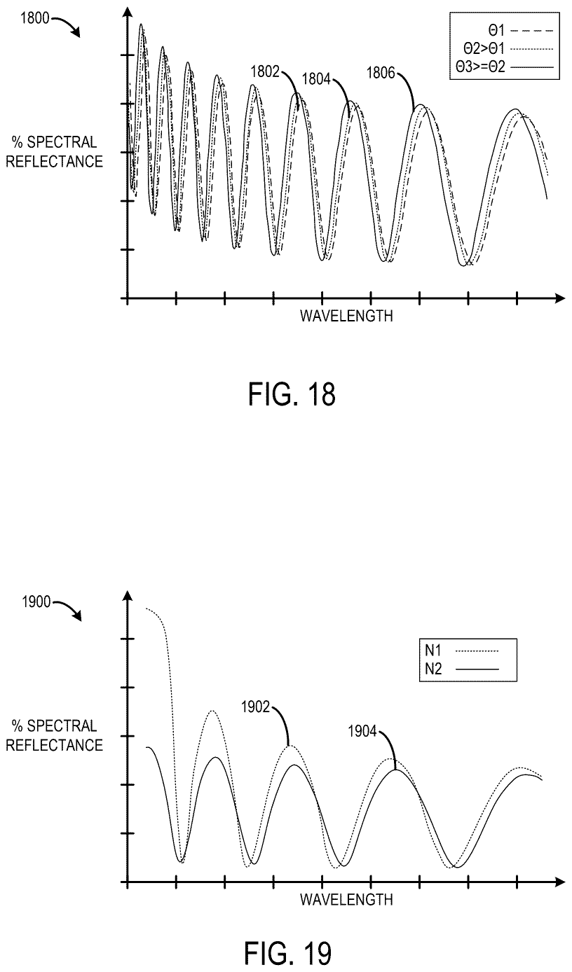

FIG. 18 shows an example graph 1800 of a plurality of plots of spectral reflectance of a material on a substrate that vary as a function of wavelength. Each of the plurality of plots corresponds a different angle of incidence of light reflected off the substrate and collected by the hyperspectral camera. The plurality of plots can be generated from hyperspectral images of the substrate. A first plot 1802 corresponds to the light having a first angle of incidence (θ1) on the material on the substrate. A second plot 1804 corresponds to the light having a second angle of incidence (θ2) on the material on the surface of the substrate. In this example, the second angle of incidence (θ2) is greater than the first angle of incidence (θ1). A third plot 1806 corresponds to the light having a third angle of incidence (θ3) on the material on the surface of the substrate. In this example, the third angle of incidence (θ3) is greater than the second angle of incidence (θ2). Note that the angle of incidence changes how the light interacts with the material on the surface of the substrate and therefore has an effect on the reflectance spectra. Stated another way, the spectral reflectance of the material is different for different angles of incidence at different wavelengths. Further, note that the variance in spectral reflectance between different angles of incidence varies non-uniformly at different wavelengths. The periodic nature of the plots 1802, 1804, 1806 are caused by interference patterns generated by light traveling through the material on the substrate.

In some implementations, the machine-learning model 132 is trained based at least on hyperspectral images of scene(s) (e.g., processing chambers) and/or object(s) (e.g., substrates) captured at different angles relative to the hyperspectral camera that captured the hyperspectral images. In some examples, the angles of the hyperspectral camera for the training hyperspectral images are selected based at least on the materials of the films on the substrates being imaged. The training hyperspectral images can be labeled with the angle of incidence of the hyperspectral camera 128 in order to train the machine-learning model 132 to make accurate predictions about spectral reflectance of a material on a substrate or other metrology data for the object being imaged. The trained machine-learning model 132 can be configured to receive one or more hyperspectral images of a substrate having a film comprising a first material captured at a first angle selected based at least on the first material of the film and output metrology data 134 for the first substrate based at least on the one or more hyperspectral images captured at the selected first angle. Further, the trained machine-learning model 132 can be configured to receive one or more hyperspectral images of a second substrate having a film comprising a second material different than the first material captured at a second angle selected based at least on the second material of the film and output metrology data 134 for the second substrate based at least on the one or more hyperspectral images captured at the second angle. In some examples, the metrology data 132 may include the spectral reflectance of a material as a function of wavelength for different angles of incidence of the hyperspectral camera 128.

In some implementations, the machine-learning model 132 can be trained to distinguish between different numbers of layers of material on a substrate and/or different thicknesses of one or more layers of material on a substrate based at least on analyzing hyperspectral images of the substrate. FIG. 19 shows an example graph 1900 of two plots of spectral reflectance of two different substrates that vary as a function of wavelength. The plots can be generated from hyperspectral images of the substrates. The two substrates have the same overall thickness and different numbers of layers. A first plot 1902 represents the spectral reflectance of a first substrate having a first number of layers (N1). A second plot 1092 represents the spectral reflectance of a second substrate having a second number of layers (N2). In this example, the second number of layers (N2) is greater than the first number of layers (N1). Note that the first plot 1902 corresponding to the first substate generally has a greater spectral reflectance than the second plot 1904 corresponding to the second substrate. The difference in spectral reflectance can be attributed to the first substrate having thicker layers than the layers of the second substrate. This information can be applied to training the machine-learning model 132. In particular, the machine-learning model 132 can be trained on hyperspectral images of different substrates having different numbers of layers and different thicknesses of layers. The trained machine learning model 132 can be configured to identify the number of layers on a substrate and/or the thicknesses of the layers on the substrate based at least on analyzing hyperspectral images of the substrate.

Stress and bow are metrics that can be employed to evaluate whether a process is being performed on a substrate as expected, as well as for process control for monitoring tool health of the processing tool 100. In some implementations, the processing tool 100 can be configured to perform scan and measurement of bow and/or stress of a substrate using the hyperspectral camera 128. Indications of stress and bow of a substrate can be manifest at least as a change in curvature resulting in some pixels of hyperspectral images of the substrate receiving more light than other pixels. Further, indications of stress and bow can be manifest at least as a shift in the reflectance spectra that will manifest itself as a simple right or left shift in spectrums that don't have fringes or a compressional wave change in the case of spectra with multiple fringes. Stress and/or bow can be measured locally at a plurality of different points across the substrate via hyperspectral imaging, and a global measurement of stress and/or bow of the substrate can be determined based at least on the plurality of local measurements of stress and/or bow.

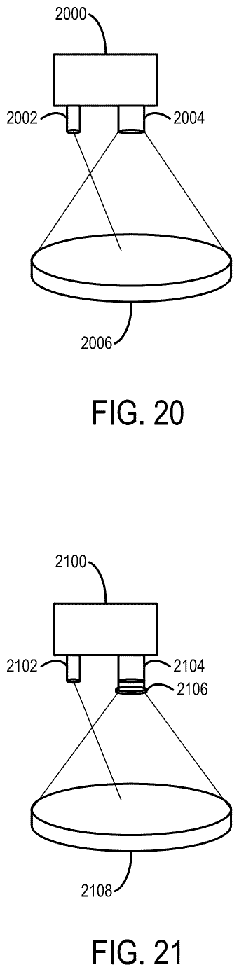

FIGS. 20-22 schematically show example configurations in which a hyperspectral camera can be used to scan and measure stress and/or bow of a substrate in a processing tool, such as the processing tool 100 shown in FIG. 1. In some implementations, the hyperspectral camera can be configured to perform in-situ scan and measurement of stress and/or bow of a substrate during a process in a processing chamber of the processing tool. In other examples, the hyperspectral camera can be configured to perform ex-situ or in-line scan and measurement of stress and/or bow of a substrate when the substrate is in a transfer module, a load lock module, or an equipment front end module (EFEM).

FIGS. 20-21 schematically show example configurations in which a hyperspectral camera can be used to simulate a spectroscopic ellipsometer to scan and measure stress and/or bow of a substrate. The measurement is based on the analysis of changes in the polarization state of light upon reflection from a substrate. Ellipsometer measurements provide information about the complex refractive index and thickness of the films on the substrate. A change in curvature of surface can change the complex refractive index and by varying the polarization of light received, the change in stress/bow can be seen as a change in ellipsometer parameters, such as Psi (Ψ), Delta (Δ), Incident Angle (Θi), Wavelength (λ), and Refractive Indices (n and k). Psi (Ψ) is the amplitude ratio of the p-polarized and s-polarized components of the reflected light. It is related to the phase shift between the two polarization states. Delta (Δ) is the phase difference between the p-polarized and s-polarized components of the reflected light. It is related to the shift in the polarization ellipse. Incident Angle (Θi) is the angle at which the light strikes the sample surface. The incident angle can affect the sensitivity of the ellipsometric measurements to thin film properties. Wavelength (λ) is the wavelength of the incident light. Ellipsometers often operate in a specific wavelength range, and measurements at different wavelengths can be used to extract more information about the sample. Refractive Indices (n and k) are the complex refractive index (n+ik) of the thin film of the substrate. The real part (n) and the imaginary part (k) are related to the amplitude and absorption of the light, respectively.

In FIG. 20, a hyperspectral camera 2000 includes a light source 2002 and an image sensor 2004. The light source 2002 emits light in different selected wavelengths across the electromagnetic spectrum (e.g., UV, visible light, near IR, IR) directly onto a substrate 2006. The image sensor 2004 captures hyperspectral images of light in the different wavelengths reflected from the substrate 2006 to the image sensor 2004. This configuration looks at changes in wavelength shift (compressional shift) and intensity from pixel to pixel as a result of curvature and/or stress induced anisotropic behavior to determine bow and/or stress measurements. As an example, a flat surface will provide an equal amount of reflected light to each pixel. However, in the case of a curved surface there is additional interference between the incident and reflected light within the dielectric film. This will result in a varying reflected light having different phase/k as well as a change in amplitude in certain wavelengths.

In FIG. 21, a hyperspectral camera 2100 includes a light source 2100, an image sensor 2104, and a polarizer 2106. The light source 2002 emits light in different wavelengths across the electromagnetic spectrum (e.g., UV, visible light, near IR, IR) directly onto a substrate 2108. The light reflected from the substrate 2108 passes through the polarizer 2106 to the image sensor 2104. The polarizer 2106 varies the polarization of the light reflected from the substrate 2108 that allows for variances in birefringence of the substrate 2108 to be observed by the image sensor 2104 in order to determine stress and/or bow of the substrate 2108. In particular, the image sensor 2104 can observe changes in reflectance of S and P light that passes through the polarizer 2106 because of stress and/or bow of the substrate. Moreover, the polarizer 2106 filters out components of the reflected light that can interfere with measurements of stress and/or bow by the hyperspectral camera 2100 amplifying the changes in birefringence relative to noise in the signal that allows for more accurate measurements of stress and/or bow. Any suitable type of polarizer may be employed by the hyperspectral camera 2100 to vary the polarization of the reflected light and filter out unwanted components of reflected light for the image sensor 2104 of the hyperspectral camera 2100. Examples include rotating polarizers, linear polarizers, elliptical polarizers, and other types of polarizers.

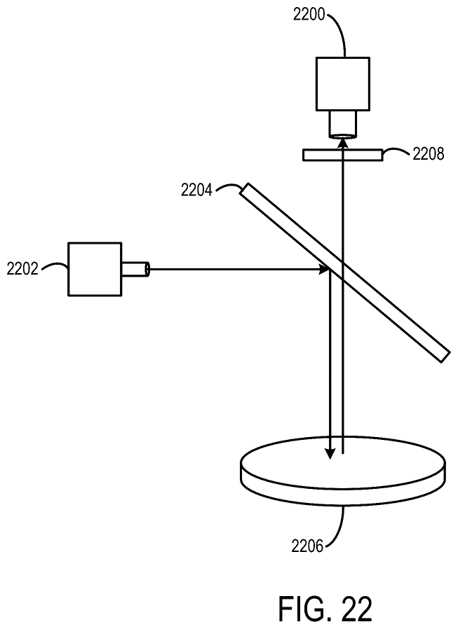

FIG. 22 schematically shows an example configuration in which a hyperspectral camera 2200 can be used to obtain both local and global stress and/or bow measurements via coherent gradient sensing. Coherent gradient sensing measures surface slopes and gradients of a substrate with high precision and involves analyzing the interference patterns of coherent light to extract information about the surface slopes by comparing the phase shift between multiple points as the optical path of the light varies. In the illustrated configuration, a coherent light source 2202 emits coherent light to a beam splitter 2204. In some implementations, the coherent light source 2202 comprises one or more lasers that produce laser light in different wavelengths. In some implementations, the coherent light source 2202 comprises a broadband light source. The coherent light emitted from the coherent light source 2202 is used to generate well-defined interference patterns. The beam splitter 2204 is configured to split the coherent light emitted from the coherent light source 2202 into two beams. One of the split beams serves as a reference beam, and the other split beam serves as a test beam that interacts with a substrate 2206. The test beam illuminates the surface of the substrate 2206, and the reflected light interacts with the surface features of the substrate 2206. The reflected test beam interferes with the reference beam, creating an interference pattern. The interference pattern is sensitive to the phase changes induced by the surface gradients of the substrate 2206, which indicate stress and/or bow. The hyperspectral camera 2200 optionally can include a pattern filter 2208 that is configured to filter out unwanted light and tailors the characteristics of the incident light on the image sensor of the hyperspectral camera 2200 to the requirements of the measurement system. The pattern filter 2208 improves the quality and accuracy of the obtained data by filtering out light that would otherwise increase noise. The choice of filters depends on factors such as the properties of the material being measured, the wavelength range of interest, and the specific requirements of the measurement setup. Example types of optical filters that can be employed in the hyperspectral camera 2200 can include a wavelength-selective filter, a spatial filter, a polarizing filter, and/or a frequency filter. An image sensor of the hyperspectral camera 2200 captures the interference pattern. The hyperspectral camera 2200 analyzes the changes in phase of the interference pattern to extract information about stress and/or bow of the substrate 2206. The hyperspectral camera 2200 generates hyperspectral images of the interference pattern in different wavelengths as the phase difference can vary based at least on the different wavelengths. In some examples, the hyperspectral images of the substrate 2206 captured by the hyperspectral camera 2200 can be used to determine the stress modulus of the substrate. In some examples, the hyperspectral images of the substrate 2206 captured by the hyperspectral camera 2200 can be used to reconstruct a three-dimensional surface profile of the substrate 2206 that indicates the stress and/or bow on the substrate.

The hyperspectral camera configurations shown in FIGS. 20-22 and described above can measure reflectance of a substrate on a pixelwise basis via hyperspectral images and across the entire substrate in order to determine stress and/or bow local at different pixels as well as globally across the surface of the substrate. In some implementations, the hyperspectral cameras can provide inline measurements of reflectance that can quickly provide insight into wafer stress and/or bow allowing for quality of recipe and tool health to be determined during a process. Furthermore, in some implementations, the processing tool 100 can be dynamically adjusted to correct any issues related to stress and/or bow of a substrate. For example, the processing tool 100 can transfer a substrate to a different processing chamber to deposit a film on the substrate backside to thereby balance stresses with that caused by frontside processing.

In some implementations, the machine-learning model 132 is trained based at least on hyperspectral images of different substrates that are affected by different levels of stress and/or bow. The trained machine-learning model 132 can be configured to receive one or more hyperspectral images of a substrate and output metrology data 134 including determinations of amounts of stress and/or bow of the substrate based at least on the one or more hyperspectral images. In some examples, the determination of stress and/or bow can be localized to different points on the substrate. In other examples, the determination of stress and/or bow applies globally across the substrate.

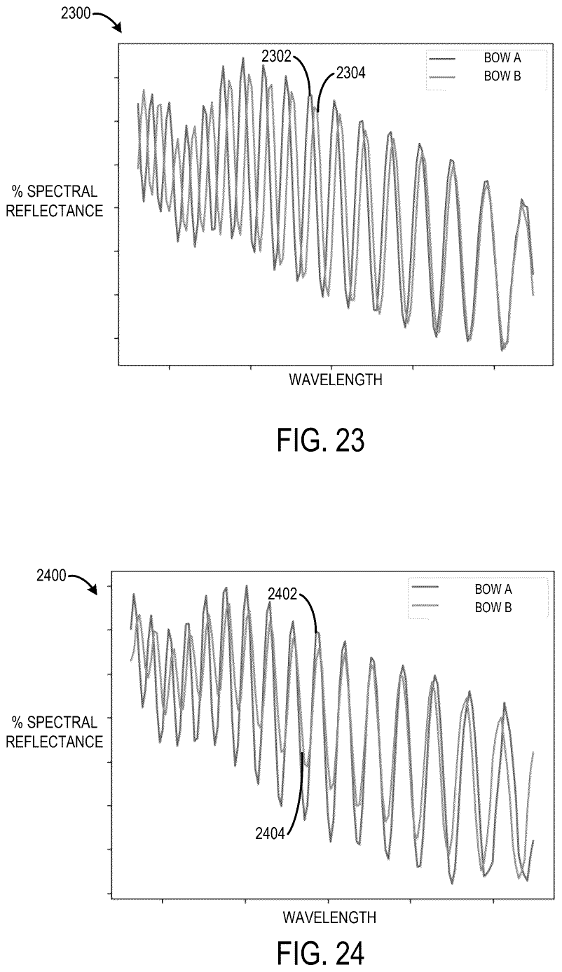

FIGS. 23-24 show example graphs of spectral reflectance measured in different wavelengths at different points on a substrate. FIG. 23 shows a graph 2300 of spectral reflectance measurements taken at a pixel corresponding to a center point of the substrate. The graph 2300 includes a first plot 2302 indicating spectral reflectance at a lowest bow point (BOW A) on the substrate within the pixel at different wavelengths and a second plot 2304 indicates spectral reflectance at a highest bow point (BOW B) on the substrate within the pixel at different wavelengths. The plots 2302 and 2304 collectively indicate the stress and/or bow of the substrate measured at the center point of the substrate.

FIG. 24 shows a graph 2400 of spectral reflectance measurements taken at a pixel corresponding to a region proximate to an edge of the substrate. The graph 2400 includes a first plot 2402 indicating spectral reflectance at a lowest bow point (BOW A) on the substrate within the pixel at different wavelengths and a second plot 2404 indicates spectral reflectance at a highest bow point (BOW B) on the substrate within the pixel at different wavelengths. The plots 2402 and 2404 collectively indicate the stress and/or bow of the substrate measured at the edge of the substrate. Comparing graph 2300 in FIG. 23 to graph 2400 in FIG. 24, plot 2404 has a longitudinal compressive shift and an amplitude difference relative plot 2304 that indicates a greater amount of stress and/or bow at the edge of the substrate relative to the center point of the substrate. When there is a curved surface or bow in the substrate, there is a phase shift and change in k vector, which is the angular wave vector of the light reflected off of the substrate. Not only does there appear to be a shift by position on the same substrate, but in the case of a different bow value, that shift appears to be more pronounced as is the case with plot 2404 relative to plot 2304.

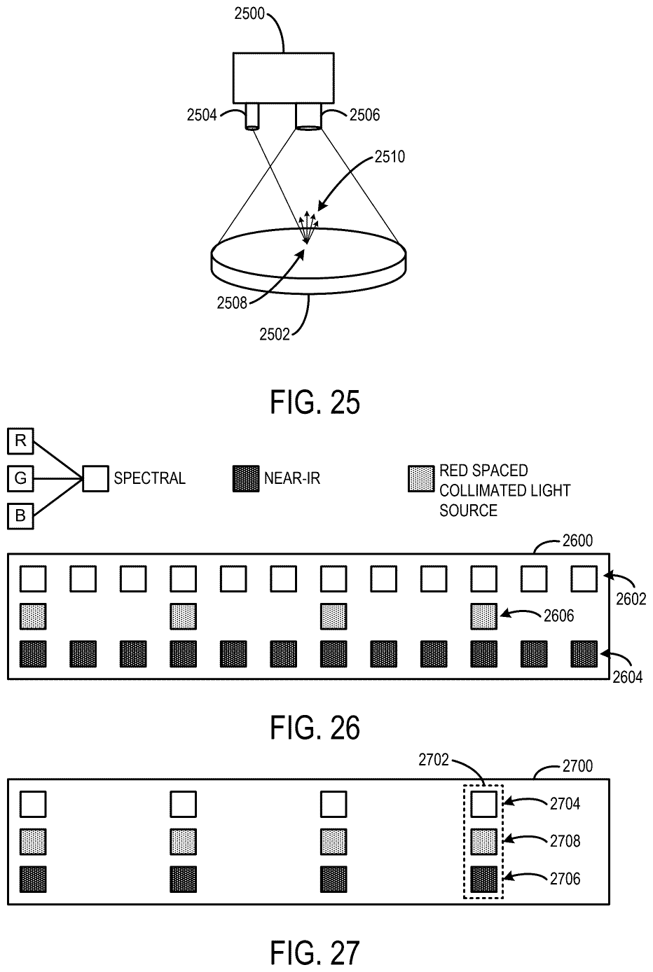

Haze is a metric that gives insight into the diffuseness of a surface and provides an indication of surface roughness. Further, the measurement of surface roughness can be used to inform and improve the accuracy of a determination of a thickness of a substrate by providing a roughness correction factor that is factored into the thickness determination. In some implementations, the processing tool 100 can be configured to measure haze of a substrate using the hyperspectral camera 128. FIG. 25 shows an example configuration in which a hyperspectral camera 2500 is configured to measure haze on a substrate 2502. In some implementations, the hyperspectral camera 2500 can be configured to perform in-situ measurements of haze of the substrate during a process in a processing chamber of the processing tool 100. In other examples, the hyperspectral camera 2500 can be configured to perform ex-situ or in-line measurements of haze of the substrate when the substrate is in a transfer module, a load lock module, a front opening unified pod (FOUP), or an equipment front end module (EFEM).

The hyperspectral camera 2500 includes a light source 2504 and an image sensor 2506. The light source 2504 includes a plurality of spatially separated light emitters. In some examples, the light emitters comprise broadband light sources. In some examples, the light emitters comprise LEDS configured to emit light in particular wavelengths. The spatially separated light emitters are configured to emit light on different spatially separated regions of the substrate 2502. Each region corresponds to a plurality of pixels that are spaced far enough apart such that light from one light emitter only emits light onto a single region and does not emit light onto other regions of the substrate 2502. In the illustrated example, light emitted from a light emitter of the light source 2504 illuminates a pixel 2508 on the substrate 2502. Surrounding pixels around the illuminated pixel 2508 will be dark when the surface is more ideally specular (smooth). When the surface is not specular, the surrounding pixels will exhibit scattered reflectance 2510. The scattered reflectance 2510 can be caused by a variety of factors including, but not limited to the presence of particles, crystal structures, defects, crystal orientation (that results in anisotropic dispersion), surface roughness (topographical variance), or any combination thereof. In one example, haze is measured by looking at a ratio of incident light to scattered light. The more angular spread there is from the point of incidence the more diffuse the surface of the substrate is. The state of the surface of the substrate will influence how incident light scatters, however with hyperspectral imaging and a broadband light source, the instrument also can show what wavelengths of light are more/less effected. This can serve as both a potential correction factor for thickness/stress as well as potentially indicate the presence of larger defects/contaminates/particles.

Note that the illustrated example shows a single pixel 2508 on the substrate 2502 being illuminated to measure haze. In other examples, various other pixels spaced apart across the substrate 2502 can be illuminated with different light emitters at the same time to measure haze in different regions of the substrate.

The plurality of spatially separated light emitters can be arranged in the light source 2504 differently in different implementations. FIGS. 26-27 schematically show example arrangements of spatially separated light emitters in a light source. In FIG. 26, a light source 2600 includes a plurality of spectral light emitter 2602, a plurality of near-IR light emitters 2604, and a plurality of collimated red-light emitters 2606. In some examples, the plurality of spectral light emitters 2602 include sets of red, green, and blue light emitters (e.g., LEDs). The spectral light emitters 2602 are evenly spaced apart from one another across the light source 2600 in this example. The near-IR light emitters 2604 are evenly spaced apart from one another across the light source 2600 in this example. The collimated red-light emitters 2606 are designated for measuring haze and are spaced farther apart relative to one another than the spectral light emitters 2602 and the near-IR light emitters 2604. Note that the different types of light emitters can have any suitable spacing on the light source 2600. By separating the collimated red-light emitters 2606 further apart than the other light emitters of the light source 2600, light emitted by these light emitters can be directed to different regions of a substrate to measure haze without light from the other collimated red-light emitters polluting the region with unintended light. In one example, in this arrangement, the collimated red-light emitters can be used to measure haze and the spectral light emitters 2602 and the near-IR light emitters 2604 can be used to perform thickness/stress/bow measurements, among other operations.

In FIG. 27, a light source 2700 includes a plurality of sets of light emitters 2702. Each set of light emitters 2702 includes one or more spectral light emitters 2704, one or more near-IR light emitters 2706, and one or more collimated red-light emitters 2708. The sets of light emitters 2702 are spaced apart from other sets of light emitters such that the sets of light emitters 2702 illuminate different regions of the substrate for haze measurements without providing light pollution to the other regions. In the illustrated example, all the light emitters in the different sets can be used to measure haze in addition to other metrics/operations (e.g., thickness, stress, bow measurements).

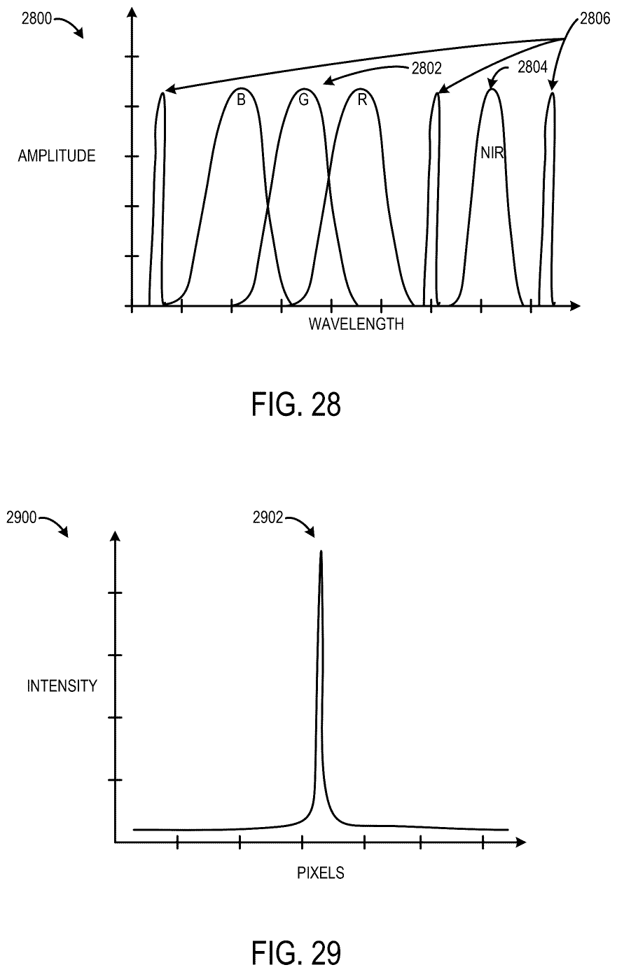

In some implementations, different wavelengths of light can be selected to illuminate a substrate to measure the haze of the substrate. FIG. 28 shows an example graph 2800 of the electromagnetic spectrum including different ranges of wavelength that can be used for different operations. In particular, light in the spectral wavelength range (e.g., red, green, blue) 2802 and the near-IR wavelength range 2804 can be designated for use in metrics, such as measuring thickness, stress, bow. Further, wavelength ranges outside of the spectral and near-IR ranges, such as wavelength ranges 2806, may be designated for measuring haze. By using the wavelength ranges 2806 for measuring haze, the spectral and near-IR wavelength ranges will not provide light pollution since these wavelength ranges are not considered when quantifying the haze of the substrate.

FIG. 29 shows an example graph 2900 including a haze measurement 2902 represented in terms of a number of pixels with reflected light and their corresponding intensity. The height of the haze measurement 2902 corresponds to smoothness of the surface and the spread of the haze measurement 2902 corresponds to roughness of the surface. The haze measurement 2902 corresponds to a single light emitter.

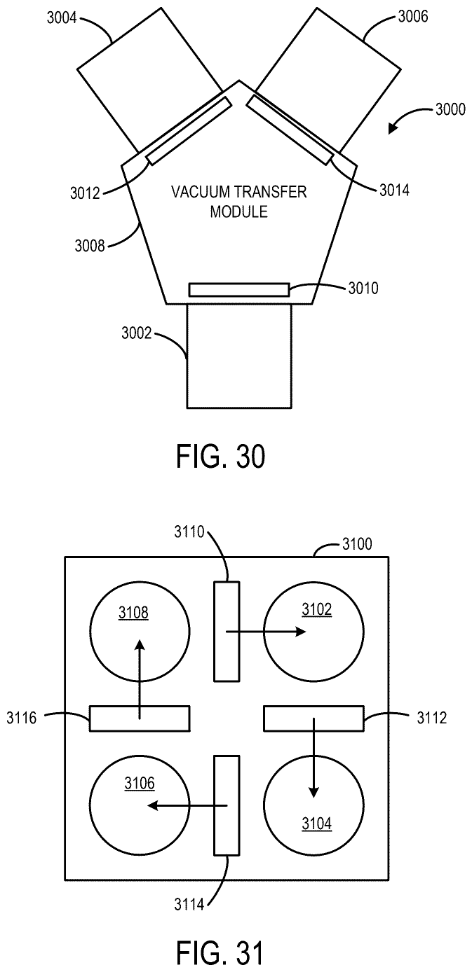

In some implementations, a processing tool includes a plurality of hyperspectral cameras positioned in different locations within the processing tool in order to provide input for control of the processing tool. FIG. 30 schematically shows an example processing tool 3000 including a plurality of modules 3002, 3004, 3006 that are connected to a vacuum transfer chamber 3008. The vacuum transfer chamber 3008 includes a plurality of hyperspectral cameras 3010, 3012, 3014 corresponding to the plurality of modules 3002, 3004, 3006. Substrates can be transferred between the different modules 3002, 3004, 3006 to perform different processes on the substrates. When a substrate is transferred from one module to another module, the substrate passes through the vacuum transfer chamber 3008 and a corresponding hyperspectral camera can capture hyperspectral image(s) of the substrate. For example, each time a substrate enters and exits a module, the corresponding hyperspectral camera can capture hyperspectral images of the substrates to determine how the substrate was changed by the process performed by the module. Furthermore, the processing tool 3000 may be configured to control how a substrate is processed based on the hyperspectral images of the substrate and corresponding analysis performed on the hyperspectral images (e.g., by the machine-learning model 132 shown in FIG. 1).

In one example, a film deposition process is performed on a substate in the module 3004. The hyperspectral camera 3012 captures hyperspectral images of the substrate before and after the process is performed. The hyperspectral images are analyzed by the machine-learning model 132 and the machine-learning model determines that the process caused the substrate to bow based at least on analysis of the hyperspectral images. The processing tool 3000 transfers the substrate to the module 3006 to perform a backside film deposition on the substrate based at least on the output of the machine-learning model 132 in order to compensate for the bow on the opposing side of the substrate. The processing tool 3000 may be configured to dynamically adjust control of the processing tool 3000 to perform any suitable processes on a substrate based at least on analysis of hyperspectral images of the substrate performed by the machine-learning model 132.

In some implementations, a module includes a plurality of hyperspectral cameras positioned in different locations within the module in order to provide input for control of processes performed by the module. FIG. 31 schematically shows an example module 3100 including a plurality of hyperspectral cameras. For example, the module 3100 may correspond to any of the modules of the processing tool 3000 shown in FIG. 30 and the processing tool 100 shown in FIG. 1. The module 3100 is configured to perform processes on four different substrates 3102, 3104, 3106, 3108 at a time. The substrates may be indexed and transferred between the four different positions within the module 3100 to perform different processes on the different substrates. The module 3100 includes four hyperspectral cameras 3110, 3112, 3114, 3116 corresponding to the four substrates 3102, 3104, 3106, 3108. The four hyperspectral cameras 3110, 3112, 3114, 3116 are configured to capture hyperspectral images of the four substrates 3102, 3104, 3106, 3108 before, during, and/or after processes are performed on the four substrates 3102, 3104, 3106, 3108. The machine-learning model 132 analyzes the hyperspectral images and outputs metrology data for the four substrates 3102, 3104, 3106, 3108. The processing tool dynamically controls the processes performed on the substrates by module 3100 based at least on the metrology data output from the machine-learning model 132.

In one example, a film deposition process is performed on the substrate 3102 in the first position in the module 3100. The hyperspectral camera 3110 captures a series of hyperspectral images of the substrate 3102 during the process. The machine-learning model 132 analyzes the series of hyperspectral images and determines that the amount of film growth on the substrate is less than expected. The processing tool dynamically adjusts the process to increase the film growth rate based at least on the output of the machine-learning model 132 in order to compensate for the determined deficiency in the amount of film growth in order to reach the expected amount of film growth on the substrate.

In another example, a film deposition process is performed on the substrate 3102 in the first position in the module 3100. The hyperspectral camera 3110 captures hyperspectral images of the substrate 3102 before and after the process is performed on the substrate 3102. The machine-learning model 132 analyzes the hyperspectral images captured by the hyperspectral camera 3110 and outputs metrology data indicating that the process performed on the substrate 3102 was deficient. The processing tool dynamically adjusts a next process that is to be performed on the substrate in a second position in the module 3100 based at least on the output of the machine-learning model 132. The substrate 3102 is moved to the second position in the module 3100 and the hyperspectral camera 3112 captures hyperspectral images of the substrate 3102 before and after the next dynamically adjusted process is performed on the substrate 3102 in the second position. The machine-learning model 132 analyzes the hyperspectral images captured by the hyperspectral camera 3112 and outputs metrology data indicating that the process performed on the substrate 3102 went as expected. So, the substrate 3102 continues being processed in the remaining positions in module 3100.

The module 3100 may be configured to dynamically adjust a process as it is being performed on a substrate based at least on analysis of hyperspectral images of the substrate performed by the machine-learning model 132. Further, the module 3100 may be configured to dynamically adjust any future processes to be performed on a substrate based at least on analysis of hyperspectral images of the substrate performed by the machine-learning model 132.

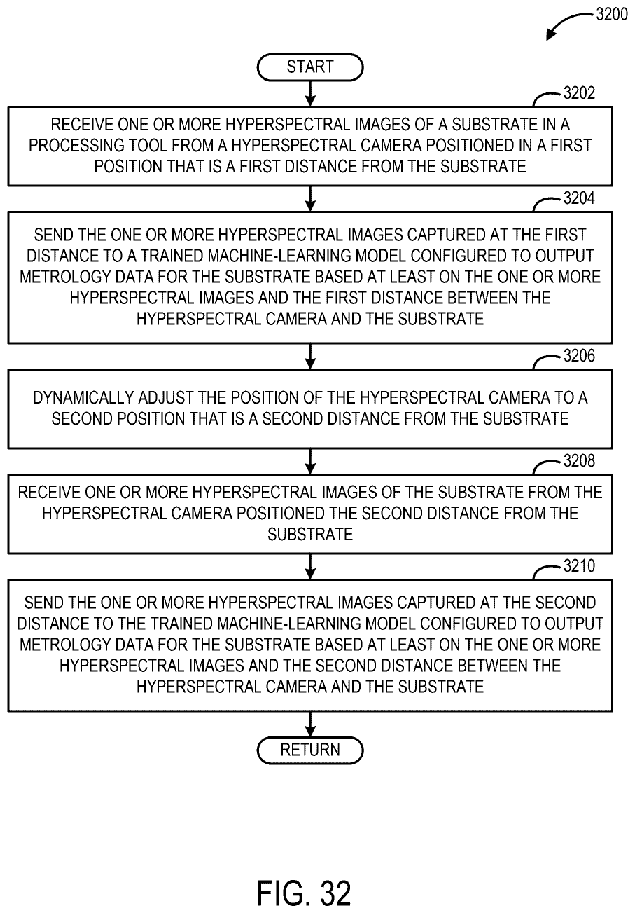

FIG. 32 shows a flow diagram depicting an example method 3200 of dynamically controlling the position of a hyperspectral camera in a processing tool to vary a distance between the hyperspectral camera and a substrate for hyperspectral imaging and analysis. For example, the method 3200 can be performed by the controller 130 of the processing tool 100 of FIG. 1. At 3202, the method 3200 includes receiving one or more hyperspectral images of a substrate in a processing tool from a hyperspectral camera positioned in a first position. At 3204, the method 3200 includes sending the one or more hyperspectral images captured at the first distance to a trained machine-learning model configured to output metrology data for the substrate based at least on the one or more hyperspectral images and the first distance between the hyperspectral camera and the substrate. At 3206, the method 3200 includes dynamically adjusting the position of the hyperspectral camera to a second position that is a second distance from the substrate. Alternatively or additionally, in some implementations, an optical component (e.g., a zoom lens) of the hyperspectral camera can be dynamically adjusted to adjust an optical distance between the hyperspectral camera and the substrate. Alternatively or additionally, in some implementations, the substrate can be moved relative to the position of the hyperspectral camera to dynamically adjust the distance between the hyperspectral camera and the substrate. At 3208, the method 3200 includes receiving one or more hyperspectral images of the substrate from the hyperspectral camera positioned the second distance from the substrate. At 3210, the method 3200 includes sending the one or more hyperspectral images captured at the second distance to the trained machine-learning model configured to output metrology data for the substrate based at least on the one or more hyperspectral images and the second distance between the hyperspectral camera and the substrate. The method 3200 can be performed to capture hyperspectral images of a substrate at different distances that are analyzed differently by the trained machine-learning model to produce different types of metrology data for the substrate that is based at least on the distance between the hyperspectral camera and the substrate when the hyperspectral images were captured. For example, the distance between the hyperspectral camera and the substrate may be set to capture hyperspectral images of the entire substrate to produce globalized metrology data for the entire substrate. Further, the distance between the hyperspectral camera and the substrate can be dynamically reduced such that the hyperspectral camera captures images of a particular feature or region of interest of the substrate to produce localized metrology data for the particular feature or region of interest of the substrate.

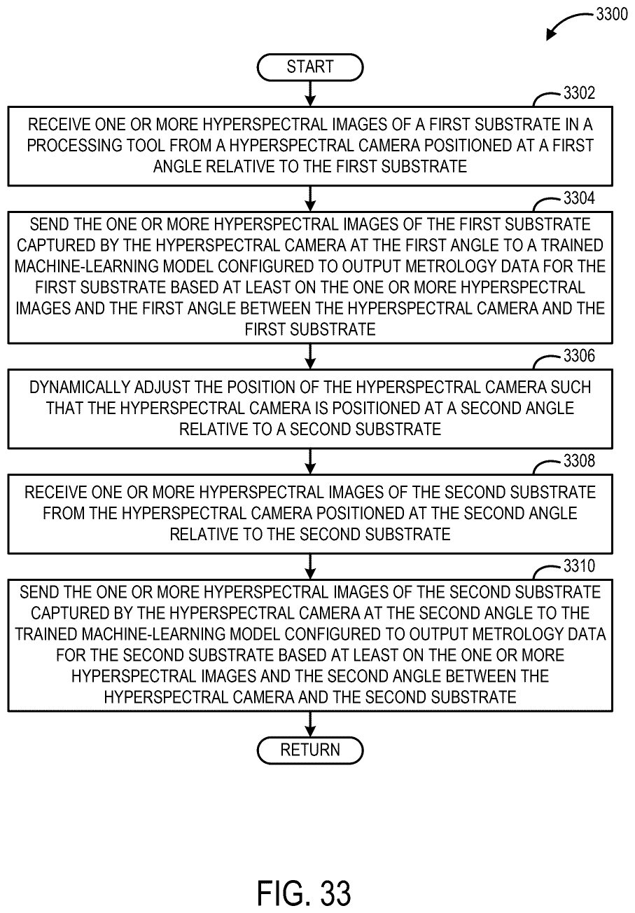

FIG. 33 shows a flow diagram depicting an example method 3300 of dynamically controlling the position of a hyperspectral camera to capture hyperspectral images of different substrates from different angles. For example, the method 3300 can be performed by the controller 130 of the processing tool 100 of FIG. 1. At 3302, the method 3300 includes receiving one or more hyperspectral images of a first substrate in a processing tool from a hyperspectral camera positioned at a first angle relative to the first substrate. At 3304, the method 3300 includes sending the one or more hyperspectral images of the first substrate captured at the first angle to a trained machine-learning model configured to output metrology data for the first substrate based at least on the one or more hyperspectral images and the first angle between the hyperspectral camera and the first substrate. At 3306, the method 3300 includes dynamically adjusting the position of the hyperspectral camera such that the hyperspectral camera is positioned at a second angle relative to a second substrate. Alternatively or additionally, in some implementations, the substrate can be moved relative to the position of the hyperspectral camera to dynamically adjust the angle between the hyperspectral camera and the second substrate. At 3308, the method 3300 includes receiving one or more hyperspectral images of the second substrate from the hyperspectral camera positioned at the second angle relative to the second substrate. At 3310, the method 3300 includes sending the one or more hyperspectral images of the second substrate captured by the hyperspectral camera at the second angle to the trained machine-learning model configured to output metrology data for the second substrate based at least on the one or more hyperspectral images and the second angle between the hyperspectral camera and the second substrate. The method 3300 can be performed to capture hyperspectral images of a different substrates at different angles that are analyzed differently by the trained machine-learning model to produce different types of metrology data for the different substrates that is based at least on the angle between the hyperspectral camera and the different substrates when the hyperspectral images were captured. For example, different substrates may include films comprising different materials that reflect incident light from different angles differently. In some examples, particular angle(s) of incidence light on a particular material may produce more accurate metrology data relative to other angles. As such, the angle between the hyperspectral camera and the substrate may be set/dynamically adjusted to capture hyperspectral images based at least on the material of the substrate.

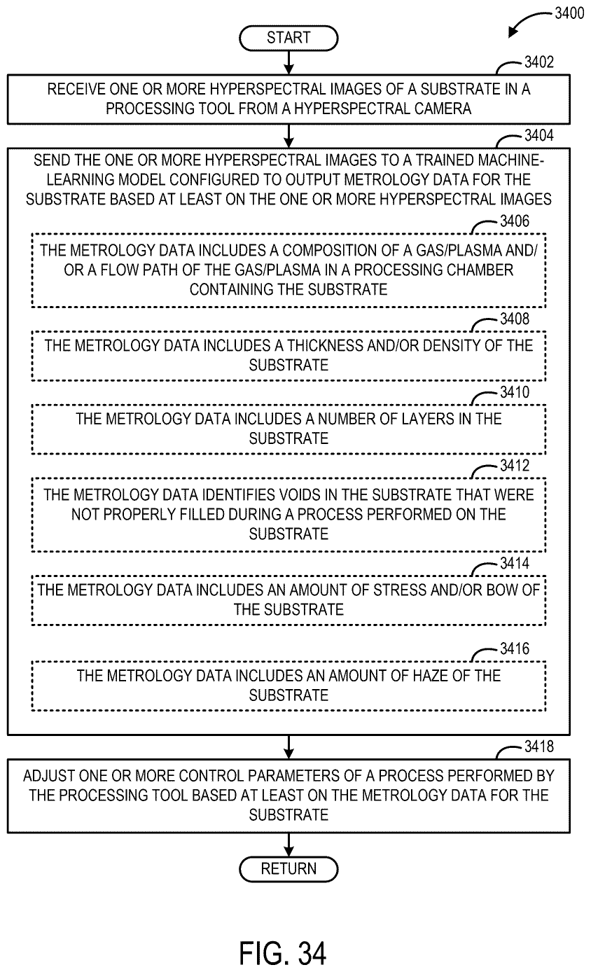

FIG. 34 shows a flow diagram depicting an example method 3300 of performing metrology-based analysis using hyperspectral images for control of a processing tool. For example, the method 3400 can be performed by the controller 130 of the processing tool 100 of FIG. 1. At 3402, the method 3400 includes receiving one or more hyperspectral images of a substrate in a processing tool from a hyperspectral camera. At 3404, the method 3400 includes sending the one or more hyperspectral images to a trained machine-learning model configured to output metrology data for the substrate based at least on the one or more hyperspectral images. In some implementations, at 3406, the metrology data may include a composition of a gas/plasma and/or a flow path of the gas/plasma in a processing chamber containing the substrate. In some implementations, at 3408, the metrology data may include a thickness and/or density of the substrate. In some implementations, at 3410, the metrology data may include the metrology data may include a number of layers in the substrate. In some implementations, at 3412, the metrology data may identify voids in the substrate that were not properly filled during a process performed on the substrate. In some implementations, at 3414, the metrology data may include an amount of stress and/or bow of the substrate. In some implementations, at 3416, the metrology data may include an amount of haze of the substrate. At 3418, the method 3400 includes adjusting one or more control parameters of a process performed by the processing tool based at least on the metrology data for the substrate. The method 3400 can provide metrology-based analysis using hyperspectral images that enables in-situ or in-line adjustment and control of the processing tool.

It will be understood that the configurations and/or approaches described herein are exemplary in nature, and that these specific embodiments or examples are not to be considered in a limiting sense, because numerous variations are possible. The specific routines or methods described herein can represent one or more of any number of processing strategies. As such, various acts illustrated and/or described can be performed in the sequence illustrated and/or described, in other sequences, in parallel, or omitted. Likewise, the order of the above-described processes can be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A processing tool comprising:
a processing chamber comprising an optical interface; and
a hyperspectral camera arranged to capture hyperspectral images of an interior of the processing chamber through the optical interface of the processing chamber.

2. The processing tool of claim 1, wherein the processing chamber comprises a pedestal and the hyperspectral camera is arranged to capture hyperspectral images of a substrate positioned on the pedestal through the optical interface.

3. The processing tool of claim 2, wherein the processing chamber comprises a showerhead situated opposite the pedestal, wherein the optical interface is disposed on the showerhead.

4. The processing tool of claim 2, wherein the optical interface is disposed on the pedestal.

5. The processing tool of claim 1, wherein the optical interface is disposed on a sidewall of the processing chamber.

6. The processing tool of claim 1, further comprising:
one or more optical elements arranged between the optical interface and the hyperspectral camera, wherein the one or more optical elements are configured to direct electromagnetic radiation passing through the optical interface to the hyperspectral camera.

7. The processing tool of claim 1, wherein the processing chamber is a plasma reactor chamber.

8. The processing tool of claim 1, further comprising a computing system configured to execute a trained machine-learning model, the trained machine-learning model configured to receive one or more hyperspectral images from the hyperspectral camera and output metrology data for the processing chamber based at least on the one or more hyperspectral images.

9. The processing tool of claim 8, wherein the computing system is configured to adjust a control parameter of a cleaning process to clean the processing chamber based at least on the metrology data for the processing chamber.

10. The processing tool of claim 8, wherein the trained machine-learning model is configured to receive a series of hyperspectral images of a substrate in the processing chamber during a substrate processing cycle and output time-based metrology data for the substrate based at least on the series of hyperspectral images of the substrate, and wherein the computing system is configured to, during the substrate processing cycle, adjust one or more control parameters of a process of the substrate processing cycle based at least on the time-based metrology data for the substrate.

11. The processing tool of claim 8, wherein the trained machine-learning model is configured to receive one or more hyperspectral images of a first substrate in the processing chamber during or after a first substrate processing cycle and output metrology data for the first substrate based at least on the one or more hyperspectral images of the first substrate, and wherein the computing system is configured to, for a second substrate processing cycle for a second substrate, adjust one or more control parameters of a process of the second substrate processing cycle based at least on the metrology data for the first substrate.

12. A computer-implemented method for controlling a processing tool, the computer-implemented method comprising:
receiving one or more hyperspectral images of a processing chamber of the processing tool from a hyperspectral camera;
sending the one or more hyperspectral images to a trained machine-learning model configured to output metrology data for the processing chamber based at least on the one or more hyperspectral images; and
adjusting one or more control parameters of a process performed by the processing tool based at least on the metrology data for the processing chamber.

13. The computer-implemented method of claim 12, wherein the process is a cleaning process to clean the processing chamber and the one or more control parameters comprise a control parameter of the cleaning process.

14. The computer-implemented method of claim 12, wherein the one or more hyperspectral images comprise a series of hyperspectral images of a substrate in the processing chamber, wherein the series of hyperspectral images of the substrate are received from the hyperspectral camera during a substrate processing cycle for the substrate, wherein the trained machine-learning model is configured to output time-based metrology data for the substrate, and wherein the one or more control parameters are adjusted during the substrate processing cycle for the substrate based at least on the time-based metrology data for the substrate.

15. The computer-implemented method of claim 12, wherein the one or more hyperspectral images comprise one or more hyperspectral images of a first substrate in the processing chamber during or after a first substrate processing cycle, and wherein the one or more control parameters are adjusted for a second substrate processing cycle for a second substrate based at least on the metrology data for the first substrate.

16. The computer-implemented method of claim 12, wherein the processing chamber is a plasma reactor chamber and the one or more hyperspectral images of the plasma reactor chamber are captured by the hyperspectral camera while plasma is present in the plasma reactor chamber, and wherein the plasma in the plasma reactor chamber is an illumination source for the hyperspectral camera.

17. A processing tool comprising:
a hyperspectral camera arranged to capture hyperspectral images of a substrate in the processing tool; and
a computing system configured to execute a trained machine-learning model, the trained machine-learning model configured to receive one or more hyperspectral images from the hyperspectral camera and output metrology data for the substrate based at least on the one or more hyperspectral images.

18. The processing tool of claim 17, wherein the metrology data includes a thickness of one or more layers of the substrate.

19. The processing tool of claim 17, wherein the metrology data includes a state of a gap in a feature of the substrate.

20. The processing tool of claim 17, wherein the hyperspectral camera has one or more of a dynamically adjustable position or a dynamically adjustable angle.

21-23. (canceled)
